(19) United States
(12) Patent Application Publication
(10) Pub. No.: US 2015/0086896 A1
(43) Pub. Date: Mar. 26, 2015

(54) MONITORING ELECTROLYTE CONCENTRATIONS IN REDOX FLOW BATTERY SYSTEMS

(71) Applicant: ENERVAULT CORPORATION, Sunnyvale, CA (US)

(72) Inventors: On Kok CHANG, San Jose, CA (US); David Andrew Sopchak, Oakland, CA (US); Ai Quoc Pham, Milpitas, CA (US); Kimio Kinoshita, Cupertino, CA (US)

(21) Appl. No.: 14/541,266

(22) Filed: Nov. 14, 2014

Related U.S. Application Data
(63) Continuation-in-part of application No. 13/432,243, filed on Mar. 28, 2012.
(60) Provisional application No. 61/468,733, filed on Mar. 29, 2011.

(51) Int. Cl. H01M 8/04; H01M 8/18; H01M 8/20; G01R 31/36

(52) U.S. Cl. CPC H01M 8/0482; G01R 31/3606; H01M 8/188; H01M 8/20; H01M 8/04291; H01M 8/04746
USPC 429/451; 324/432

(57) ABSTRACT

Methods, systems and structures for monitoring, managing electrolyte concentrations in redox flow batteries are provided by introducing a first quantity of a liquid electrolyte into a first chamber of a test cell and introducing a second quantity of the liquid electrolyte into a second chamber of the test cell. The method further provides for measuring a voltage of the test cell, measuring an elapsed time from the test cell reaching a first voltage until the test cell reaches a second voltage; and determining a degree of imbalance of the liquid electrolyte based on the elapsed time.

### RELATED APPLICATIONS

This application is a continuation-in-part of U.S. patent application Ser. No. 13/432,243, filed Mar. 28, 2012 (published as U.S. Patent Application Publication No. 2013/0084506), which claims the benefit of priority to U.S. Provisional Patent Application No. 61/468,733, filed Mar. 29, 2011, the entire contents of both documents are incorporated herein by reference.

### STATEMENT REGARDING FEDERALLY SPONSORED RESEARCH

Inventions included in this patent application were made with Government support under DE-OE0000225 “Recovery Act—Flow Battery Solution for Smart Grid Renewable Energy Applications” awarded by the US Department of Energy (DOE). The Government has certain rights in these inventions.

### FIELD OF THE INVENTION

This invention generally relates to reduction-oxidation (redox) flow batteries and more particularly to monitoring and characterizing reactant concentrations in liquid flow battery electrolytes.

### BACKGROUND

Flow batteries are electrochemical energy storage systems in which electrochemical reactants are dissolved in liquid electrolytes (sometimes referred to generically as “reactants”), which are pumped through reaction cells where electrical energy is either converted to or extracted from chemical potential energy in the reactants by way of reduction and oxidation reactions. In applications where megawatts of electrical energy must be stored and discharged, a redox flow battery system may be expanded to the required energy storage capacity by increasing tank sizes and expanded to produce the required output power by increasing the number or size of electrochemical cells or cell blocks. A variety of flow battery chemistries and arrangements are known in the art.

In some redox flow battery systems based on the Fe/Cr redox couple, the catholyte (in the positive half-cell) contains FeCl₃, FeCl₂ and HCl. The anolyte (in the negative half-cell) contains CrCl₃, CrCl₂ and HCl. Such a system is known as an “un-mixed reactant” system. In a “mixed reactant” system, the anolyte also contains FeCl₂, and the catholyte also contains CrCl₃. In an initial state of either case, the catholyte and anolyte typically have equimolar reactant concentrations.

After a number of charge/discharge cycles, the catholyte and anolyte may become imbalanced because of side reactions during a charge and/or discharge operations. For example, in the case of an Fe/Cr redox flow battery, a hydrogen generation side-reaction occurs at the anode during the charge cycle. Such side reactions cause an imbalance in electrolyte concentrations by converting more reactant in one half-cell to a higher SOC state than occurs in the second electrolyte. In this unbalanced state, for example, the concentration of Fe³⁺ may be higher than that of Cr²⁺. The imbalance decreases capacity of the battery and is undesirable. The proportion of hydrogen gas generated, and thus the degree of reactant imbalance, also increases as the state-of-charge (SOC) of the flow battery increases.

The imbalanced state may be corrected by processing the catholyte in a re-balancing cell. One example is an Iron/Hydrogen fuel cell as described in U.S. Pat. No. 4,159,366, which describes an electrolytic re-balance cell configured to oxidize waste hydrogen at a re-balance cell anode and reduce excess Fe³⁺ ions to Fe²⁺ ions at a re-balance cell cathode. H₂ may be recycled from the Cr species electrolyte and directed into the re-balance cell along with a portion of the Fe electrolyte. A catalyst may be used to promote the reaction with or without application of an applied voltage. Another example of a similar cell is provided in “Advancements in the Direct Hydrogen Redox Fuel Cell” by Khalid Fatih, David P. Wilkinson, Franz Moraw, Alan Ilicic and Francois Girard, published electronically by the Electrochemical Society Nov. 26, 2007.

Monitoring or measuring the state of charge and the imbalance of electrolytes presents additional challenges. Such concentrations may be measured spectroscopically, as described for example in U.S. Pat. No. 7,855,005 to Sahu, or by any number of other methods.

### SUMMARY

In one embodiment method, a degree of electrolyte imbalance in a reduction-oxidation (redox) flow battery system is determined by introducing a first liquid electrolyte into a first chamber of a test cell; introducing a second liquid electrolyte into a second chamber of the test cell; measuring a voltage of the test cell; measuring an elapsed time from the test cell reaching a first voltage until voltage test end-point is reached; and determining a concentration of at least one reactant in the first and/or second liquid electrolytes based on the elapsed time.

In another embodiment, an electronic controller has a processor and has a non-transitory computer-readable medium coupled to the processor and containing processor-executable instructions to perform operations for introducing a first liquid electrolyte into a first chamber of a test cell, introducing a second liquid electrolyte into a second chamber of the test cell, measuring a voltage of the test cell, measuring an elapsed time from the test cell reaching a first voltage until voltage test end-point is reached, and determining a concentration of at least one reactant in the first and/or second liquid electrolytes based on the elapsed time.

In an additional embodiment, a reduction-oxidation (redox) flow battery system has a redox flow battery, a test cell fluidically coupled to the flow battery, and the electronic controller for monitoring and controlling the test cell.

A further embodiment method of evaluating a state-of-oxidation (SOO) of an electrolyte in a reduction-oxidation (redox) flow battery system, may include flowing a first sample of a first liquid electrolyte having an unknown first SOO into a first chamber of a first test cell in a first flow; flowing a second sample of the first liquid electrolyte having the first SOO into a second chamber of the first test cell in a second flow; stopping the first flow; and while the first flow is stopped, continuing the second flow at a known flow rate while performing: charging the first test cell with a first known charging current from a first charging start time to a first predetermined stop point; measuring a first open circuit voltage of the first test cell while charging the first test cell; measuring a first total charging time from the first charging start time until the first predetermined stop point is reached; determining the first SOO of the first liquid electrolyte based on the first total charging time.

A embodiment method may further comprise flowing a first sample of a second liquid electrolyte having an unknown second SOO into a first chamber of a second test cell in a third flow, introducing a second sample of the second liquid electrolyte having the second SOO into a second chamber of the second test cell in a fourth flow, stopping the third flow, and, while the third flow is stopped, continuing the fourth flow at a known flow rate while: charging the second test cell with a second known charging current from a second charging start time to a second predetermined stop point, measuring a second open circuit voltage of the second test cell while charging the second test cell, measuring a second total charging time from the second charging start time until the second predetermined stop point is reached, and determining the second SOO of the second liquid electrolyte based on the second total charging time. An embodiment method may further comprise determining an imbalance between the first state of oxidation and the second state of oxidation by calculating a difference between the first state of oxidation and the second state of oxidation.

In an embodiment method, a first internal volume of the first half-cell chamber may be substantially equal to a second internal volume of the second half-cell chamber. In an embodiment method, charging the first test cell with the first known charging current may comprise charging the first test cell using pulsed charging in which in the first known charging current is applied during a first time interval followed by a second time interval during which the first known charging current is switched off. The application of the first known charging current during the first time interval followed by the switching off of the first known charging current during the second time interval may be repeated until the first predetermined stop point is reached. In an embodiment method, measuring he first open circuit voltage of the first test cell may comprise measuring the first open circuit voltage of the first test cell during the second time intervals when the first known charging current is switched off. In an embodiment method, the first predetermined stop point comprises a point in time at which a maximum rate of change of the first measured open circuit voltage is reached. In an embodiment method, the first predetermined stop point comprises a predetermined open-circuit voltage for the first open circuit voltage. In an embodiment method, the first predetermined stop point may comprise a predetermined closed-circuit voltage. In an embodiment method, the first liquid electrolyte may be a positive electrolyte of the flow battery, and charging the first cell may increase the state of oxidation of the positive electrolyte to a second state of oxidation. In an embodiment method, the first state of oxidation may describe a quantity of Fe3+ in the first liquid electrolyte. In an embodiment method, the second state of oxidation describes a quantity of Cr2+ in the first liquid electrolyte. An embodiment method may further comprise measuring an electric potential of at least one of the first liquid electrolyte and the second liquid electrolyte with a reference electrode.

An embodiment redox flow battery may comprise an embodiment electrolyte monitoring system for controlling operation of the flow battery according to a state of oxidation (SOO) of at least one flow battery electrolyte. An embodiment electrolyte monitoring system may comprise a first test cell having a first half-cell chamber and a second half-cell chamber, and a separator membrane separating the first half-cell chamber from the second half-cell chamber; a first supply conduit directing a first flow of a first electrolyte having an unknown first SOO into the first half-cell chamber of the first test cell and a first return conduit returning the first flow of the first electrolyte to a source of the first electrolyte; a second supply conduit directing a second flow of the first electrolyte into the second half-cell chamber of the first test cell and a second return conduit returning the second flow of the first electrolyte to the source of the first electrolyte; at least one electronically-controlled valve configured to stop the first flow of the first electrolyte through the first half-cell of the first test cell; a first electronic controller configured to control the at least one electronically-controlled valve and the first test cell. In an embodiment, the first electronic controller may comprise instructions to perform operations comprising: stopping the first flow, and continuing the second flow at a known flow rate while performing operations comprising: charging the first test cell with a first known charging current from a first charging start time to a first predetermined stop point, measuring a first open circuit voltage of the first test cell while charging the first test cell, measuring a first total charging time from the first charging start time until the first predetermined stop point is reached, and determining the first SOO of the first electrolyte based on the first total charging time. In an embodiment redox flow battery, the first electrolyte may be a positive flow battery electrolyte, and the first half-cell may be a negative half-cell of the test cell. In an embodiment redox flow battery, the first electrolyte may be a negative flow battery electrolyte, and the first half-cell may be a positive half-cell of the test cell. In an embodiment redox flow battery, the first SOO may be associated with a quantity of Fe3+ in the first liquid electrolyte. In an embodiment redox flow battery system, a first internal volume of the first half-cell chamber may be substantially equal to a second internal volume of the second half-cell chamber. In an embodiment redox flow battery system, a first internal volume of the first half-cell chamber may be smaller than a second internal volume of the second half-cell chamber. In embodiments, controlling operation of the flow battery according to a state of oxidation (SOO) of at least one flow battery electrolyte may comprise operating flow battery components such as one or more pumps, one or more valves, a communications device, a rebalancing cell, a rebalancing system, or other components.

An embodiment electrolyte monitoring system may further comprise: a second test cell having a first half-cell chamber, a second half-cell chamber, and a separator membrane separating the first half-cell chamber from the second half-cell chamber, a third supply conduit directing a third flow of a second electrolyte having a unknown second state-of-oxidation into the first half-cell chamber of the second test cell and a third return conduit returning the third flow of the second electrolyte to a source of the second electrolyte, a fourth supply conduit directing a fourth flow of the second electrolyte into the second half-cell chamber of the second test cell and a fourth return conduit returning the fourth flow of the second electrolyte to the source of the second electrolyte, a second at least one electronically-controlled valve configured to stop the third flow of the second electrolyte through the first half-cell of the second test cell, a second electronic controller configured to control the second at least one electronically-controlled valve and the second test cell, the embodiment electronic controller may comprise instructions to perform operations further comprising: stopping the third flow, and while the third flow is stopped, continuing the fourth flow at a known flow rate while performing operations that may comprise: charging the second test cell with a second known charging current from a second charging start time to a second predetermined stop point, measuring a second open circuit voltage of the second test cell while charging the second test cell, measuring a second total charging time from the second charging start time until the second predetermined stop point is reached, and determining the second state of oxidation of the second electrolyte based on the first total charging time.

In an embodiment redox flow battery, a first electronic controller or a second electronic controller may further comprise instructions for determining a degree of imbalance between the first state of oxidation and the second state of oxidation by calculating a difference between the first state of oxidation and the second state of oxidation. In an embodiment redox flow battery, the second state of oxidation may describe a quantity of Cr2+ in the first liquid electrolyte.

### BRIEF DESCRIPTION OF DRAWINGS

The accompanying drawings, which are incorporated herein and constitute part of this specification, illustrate exemplary embodiments of the invention, and together with the general description given above and the detailed description given below, serve to explain the features of the invention.

FIG. 1 is a schematic diagram illustrating a redox flow battery system including an electrolyte monitoring system according to one or more embodiments.

FIG. 2 is a diagram illustrating a cross-sectional view of an electrolyte monitoring test cell according to one or more embodiments.

FIG. 3 is a diagram illustrating an exploded view of an electrolyte monitoring test cell according to one or more embodiments.

FIG. 4 is a diagram illustrating an exploded view of another embodiment of an electrolyte monitoring test cell.

FIG. 5 is a diagram illustrating a plan view of a chamber layer of an electrolyte monitoring test cell embodiment of FIG. 4.

FIG. 6A is a schematic diagram illustrating an embodiment through-flow fluid delivery system for an electrolyte monitoring system.

FIG. 6B is a schematic diagram illustrating an embodiment reciprocating-flow fluid delivery system for an electrolyte monitoring system.

FIG. 7A is a graph illustrating a relationship between electrolyte potential vs. concentration difference for an Fe/Cr flow battery system, with points illustrating a balanced electrolyte solution.

FIG. 7B is a graph illustrating a relationship between electrolyte potential vs. concentration difference for an Fe/Cr flow battery system, with points illustrating a positively unbalanced electrolyte solution.

FIG. 7C is a graph illustrating a relationship between electrolyte potential vs. concentration difference for an Fe/Cr flow battery system, with points illustrating charging of an unbalanced electrolyte solution.

FIG. 7D is a graph illustrating a relationship between test cell OCV vs. change in concentration difference for an Fe/Cr flow battery system, with points illustrating charging of an unbalanced electrolyte solution.

FIG. 7E is a graph illustrating a relationship between test cell OCV vs. time during charging of an un-balanced electrolyte in a test cell.

FIG. 7F is a graph illustrating a relationship between test cell OCV vs. change in concentration difference during charging of a balanced electrolyte in a test cell.

FIG. 7G is a graph illustrating a relationship between electrolyte potential vs. concentration difference for an Fe/Cr flow battery system, with points illustrating a negatively unbalanced electrolyte solution.

FIG. 8 is a graph illustrating a relationship between cell voltage vs. time illustrating charging of several samples of known imbalance.

FIG. 9A is a schematic diagram illustrating of an embodiment reference electrode.

FIG. 9B is a schematic diagram illustrating of another embodiment reference electrode.

FIG. 9C is a schematic diagram illustrating of an embodiment reference electrode coupled to a junction in an electrolyte conduit.

FIG. 10A is a graph illustrating a relationship between electrolyte potential vs. concentration difference for an Fe/Cr flow battery system, illustrating points in an embodiment process for measuring a reactant concentration using a reference electrode.

FIG. 10B is a graph illustrating a relationship between potential vs. change in concentration difference for an embodiment process of FIG. 10A.

FIG. 10C is a graph illustrating a relationship between electrolyte potential vs. concentration difference for an Fe/Cr flow battery system, illustrating points in an embodiment process for measuring a reactant concentration using a reference electrode.

FIG. 10D is a graph illustrating a relationship between potential versus change in concentration difference for an embodiment process of FIG. 10C.

FIG. 11A is a graph illustrating a section of an electrolyte potential vs. concentration difference curve for an Fe/Cr flow battery system, illustrating points in an embodiment process for measuring a reactant concentration without a reference electrode.

FIG. 11B is a graph illustrating a section of an electrolyte potential vs. concentration difference curve for an Fe/Cr flow battery system, illustrating points in an embodiment process for measuring a reactant concentration without a reference electrode.

FIG. 11C is a graph illustrating change in test cell OCV versus change in reactant concentration for an embodiment process of FIG. 11A.

FIG. 11D is a graph illustrating a relationship between change in test cell OCV vs. change in reactant concentration for an embodiment process of FIG. 11B.

FIG. 12A is a process flow table illustrating an embodiment control process for measuring a degree of imbalance in a pair of flow battery electrolytes.

FIG. 12B is a schematic diagram illustrating an embodiment fluid delivery system that may be used with an embodiment process of FIG. 12A

FIG. 13A is a process flow table illustrating an embodiment control process for measuring a concentration of a charged electrolyte reactant in a flow battery electrolyte.

FIG. 13B is a schematic diagram illustrating an embodiment fluid delivery system that may be used with an embodiment process of FIG. 13A

FIG. 14A is a process flow table illustrating an embodiment control process for measuring both a concentration of a charged electrolyte reactant in at least one electrolyte and a degree of imbalance in a pair of flow battery electrolytes.

FIG. 14B is a schematic diagram illustrating an embodiment fluid delivery system that may be used with an embodiment process of FIG. 14A

FIG. 15 is a graph illustrating a relationship between time vs. imbalance for Fe/Cr flow battery electrolytes.

FIG. 16 is a linearized graph illustrating a relationship between time vs. imbalance for Fe/Cr flow battery electrolytes.

FIG. 17 is a graph illustrating a relationship between OCV vs. time illustrating several empirically-determined curves for samples of known imbalance.

FIG. 18 is a schematic diagram illustrating an embodiment electronic controller for monitoring and controlling a test cell.

FIG. 19 is a flow diagram illustrating an embodiment method of determining a degree of electrolyte imbalance in a reduction-oxidation (redox) flow battery system.

FIG. 20 is a schematic diagram illustrating an embodiment fluid delivery system that may be used with a flowing-stagnant SOO determination test.

FIG. 21 is a flow diagram illustrating an embodiment method of determining an SOO of an electrolyte in a reduction-oxidation flow battery system.

### DETAILED DESCRIPTION

As used herein, the phrase “state of charge” and its abbreviation “SOC” refer to the ratio of stored electrical charges (measured in ampere-hour) to charge storage capacity of a complete redox flow battery system. In particular, the terms “state of charge’ and “SOC” may refer to an instantaneous ratio of usable charge stored in the flow battery to the full ideal charge storage capacity of the flow battery system. In come embodiments, “usable” stored charge may refer to stored charge that may be delivered at or above a threshold voltage (e.g. about 0.7 V in some embodiments of an Fe/Cr flow battery system). In some embodiments, the ideal charge storage capacity may be calculated excluding the effects of unbalanced electrolytes.

As used herein the phrase “state of oxidation” and its abbreviation “SOO” refer to the chemical species composition of at least one liquid electrolyte. In particular, state of oxidation and SOC refer to the proportion of reactants in the electrolyte that have been converted (e.g. oxidized or reduced) to a “charged” state from a “discharged” state. For example, in a redox flow battery based on an iron/chromium (Fe/Cr) redox couple, the state of oxidation of the catholyte (positive electrolyte) may be defined as the ratio or percent of total Fe which has been oxidized from the ferrous iron (Fe²⁺) form to the ferric iron (Fe³⁺) form. The state of oxidation of the anolyte (negative electrolyte) may be defined as the negative percent of total Cr which has been reduced from the Cr³⁺ form to the Cr²⁺ form.

As used hererin, SOO may also be defined and expressed in terms of a concentration of one or more reactants in an electrolyte. For example, SOO may be expressed as a molar concentration (e.g., indicated as #.# M herein) of a charged reactant species (i.e., the numerator of the ratios described above expressed per unit volume). In some cases, the SOO of the negative electrolyte may be given a negative sign, and the SOO of the positive electrolyte may be given a positive sign. In such cases, the sum of the negative electrolyte SOO and the positive electrolyte SOO may be equal to an electrolyte imbalance. Electrolytes may be described as un-balanced or as having an imbalance when a quantity of a charged active material in one electrolyte is greater than the quantity of the charged active material in the second electrolyte. For example, a positive imbalance exists between two flow battery electrolytes when the positive electrolyte contains a greater quantity of charged active material than a quantity of charged active material in the negative electrolyte. On the other hand, a negative imbalance exists between two flow battery electrolytes when the negative electrolyte contains a greater quantity of charged active material than a quantity of charged active material in the positive electrolyte. Those “quantities” may be molar concentrations, number of moles of reactant, percentages, or quantities of any other suitable units.

Although many of the embodiments herein are described with reference to an Fe/Cr flow battery chemistry, it should be appreciated with the benefit of the present disclosure that some embodiments are applicable to flow battery systems (and some hybrid flow battery systems) using other reactants.

In some embodiments, the state of oxidation of the two electrolytes may be changed or measured independent of one another. Thus, the terms “state of oxidation” and “SOO” may refer to the chemical composition of only one electrolyte, or of both electrolytes in an all-liquid redox flow battery system. The state of oxidation of one or both electrolytes may also be changed by processes other than desired charging or discharging processes. For example, undesired side reactions may cause oxidation or reduction of active species in one electrolyte without producing a corresponding reaction in the second electrolyte. Such side reactions may cause the respective SOCs of the positive and negative electrolytes to become imbalanced such that one electrolyte has a higher effective SOC than the other.

For an Fe/Cr redox flow battery, the SOO of the positive electrolyte may be defined as the ratio of the concentration of Fe³⁺ in the electrolyte to the total concentration of Fe (i.e. the sum of Fe³⁺ and Fe²⁺ concentrations) in the electrolyte. Similarly, the SOO of the negative electrolyte is defined as the ratio of the concentration of Cr²⁺ in the electrolyte to the total concentration of Cr (i.e. the sum of Cr³⁺ and Cr²⁺ concentrations) and may be expressed as a negative number. In equation form, these are:

SOOₚₒₛ=Fe³⁺/(Fe³⁺+Fe²⁺) [1]

SOO_{neg}=−Cr²⁺/(Cr²⁺+Cr³⁺) [2]

### Unequal Mixed Reactant

Flow battery electrolytes may be formulated such that in both positive and negative electrolytes are identical in a fully discharged state. Such a system may be referred to as a “mixed reactant” system, an example of which is described in U.S. Pat. No. 4,543,302. In some embodiments, a mixed reactant electrolyte that contains unequal concentrations of FeCl₂ and CrCl₃ in the initial electrolyte (fully discharged) can be used to minimize the inequality in concentrations of CrCl₂ and FeCl₃, and to mitigate H₂ evolution during operation of a flow battery system. One example of the composition in the fully discharged state is 1M FeCl₂/1.1M CrCl₃/2-3M HCl. In such embodiments, the concentration of CrCl₃ is intentionally made higher than that of FeCl₂ in an initially-prepared and fully-discharged electrolyte solution. Upon charge, the SOO of CrCl₂ will be lower than that of FeCl₃, thereby avoiding high SOO conditions at the Cr electrode where H₂ evolution is a greater problem. With this unequal mixed reactant, the Fe electrode can be charged to nearly 100% while the Cr electrode may be charged to a lower SOO.

The Fe ionic species (Fe³⁺, Fe²⁺) at the positive electrode have a total concentration Feₜ=Fe³⁺+Fe²⁺. Correspondingly, the Cr ionic species (Cr³⁺, Cr²⁺) at the negative electrode have a total concentration Crₜ=Cr³⁺+Cr²⁺. In embodiments of an unequal mixed reactant electrolyte, Feₜ does not equal Crₜ, and the concentration of ionic species Fe³⁺, Fe²⁺, Cr³⁺ and Cr²⁺ vary widely with SOO.

The rate of H₂ evolution is enhanced at more negative potentials, which occurs as the Cr electrode becomes more fully charged. During charge, the ratio of the concentration of Cr²⁺ to the concentration of Cr³⁺ (i.e. Cr²⁺/Cr³⁺) increases, which is reflected in the more negative potential of the Cr electrode. By adding excess Cr³⁺, this ratio will be lower and the potential of the Cr electrode will be less negative and H₂ evolution will be mitigated.

For example, the maximum charge that can be inputted to a cell with a mixed reactant with unequal concentrations of FeCl₂ and CrCl₃ at 0% SOO (fully discharged) of 1M FeCl₂/1.1M CrCl₃/2M HCl is limited by the lower concentration of the electroactive species in the anolyte or catholyte. In this case, the lower concentration is 1M FeCl₂. The effect of excess CrCl₃ on SOO can be seen in the following example. During charge, if nearly the entire 1M FeCl₂ is oxidized to FeCl₃, then PosSOO is nearly 100%. At the same time approximately the same amount (1M) of CrCl₃ is reduced to CrCl₂, making the NegSOO approximately 91% (1.0/1.1). In this example, the maximum SOO of the unequal mixed reactant composition is a function of the excess amount of CrCl₃ and the concentration of FeCl₂.

In some embodiments, an unequal mixed reactant may also provide advantages with respect to cell voltage. The cell voltage calculated using a Nernst potential relationship is 1.104 V for a cell containing equimolar mixed reactant (i.e. 1M FeCl₂/1M CrCl₃/1M HCl) that is charged to 90% SOO.

This can be compared with a cell with an unequal mixed reactant containing an excess of Cr³⁺ with a composition of 1M FeCl₂/1.1M CrCl₃/1M HCl. When the PosSOO is 90% for the positive electrode (Fe electrode), the negative electrode (Cr electrode) NegSOO is 81.8% and the cell voltage is 1.084 V. By adding a slight excess of Cr³⁺, the cell voltage is lower by 20 mV and the SOO of the negative electrode is lower by about 8%. These two factors are beneficial for mitigating H₂ evolution at higher SOO, and help enhance energy efficiency.

Similar advantages may be achieved in flow battery electrolytes based on other redox couples in which parasitic side-reactions become increasingly likely as one electrode approaches a high SOO.

In some embodiments, if flow battery electrolytes contain un-equal concentrations of total active materials, then a perfectly balanced pair of charged electrolytes will each contain equal amounts of both charged species (e.g., equal quantities of Fe³⁺ and Cr²⁺), but the SOO of the two electrolytes will be different. For example, in an un-equal mixed reactant Fe/Cr flow battery, the total concentration of Fe may be less than the total concentration of Cr (e.g., total Fe=1.3M and total Cr=1.4M in some embodiments). In such a system, the absolute value of SOO of the negative electrolyte may be smaller than the absolute value of SOO of the positive electrolyte even when the charged species are in balance. For example, if Cr²⁺ and Fe³⁺ are both 0.7M, the SOO of the negative electrolyte is −0.7/1.4=−0.50; The SOO of the positive electrolyte is 0.7/1.3=0.54.

The embodiments below include systems and methods for characterizing concentrations of dissolved reactant species in flow battery electrolytes, including systems and methods for quantifying electrolyte imbalance. Although many of the embodiments are described with reference to Fe/Cr flow batteries, the same principles and concepts may also be applied to other flow battery chemistries.

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

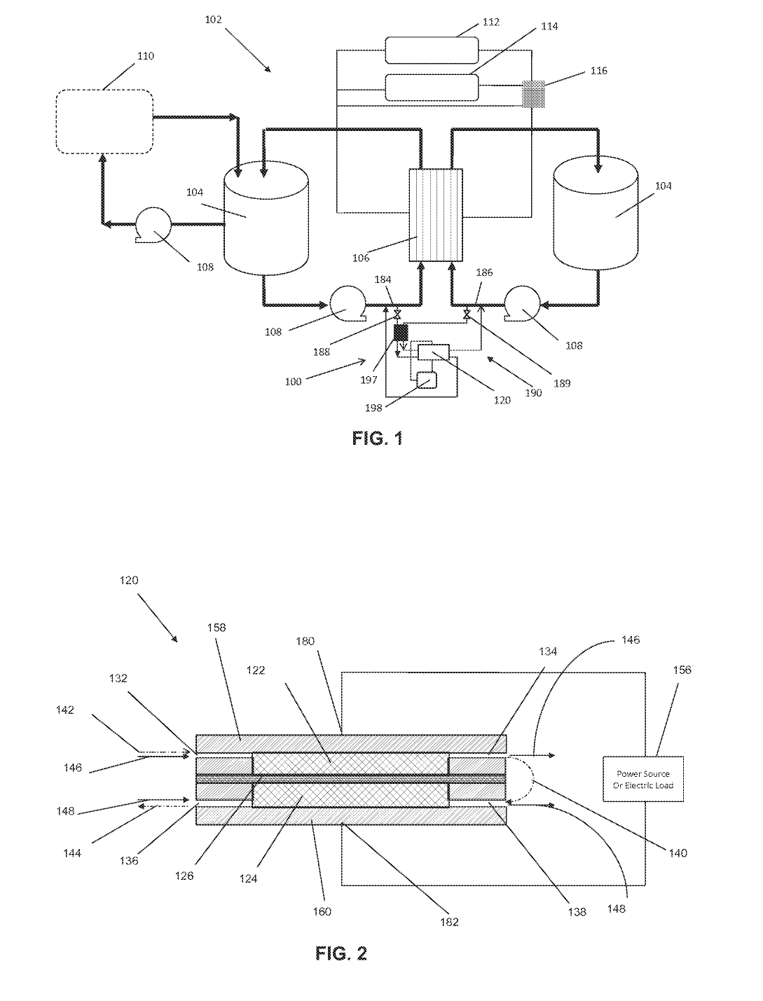

As illustrated in FIG. 1, some embodiments of an electrolyte concentration monitoring system 100 may be integrated into a redox flow battery system 102. A redox flow battery system 102 such as that shown in FIG. 1 may comprise electrolyte tanks 104 fluidically joined to a flow battery stack assembly 106. In some embodiments, a redox flow battery system 102 may comprise four separate tank volumes that may be configured to keep charged electrolytes separated from discharged electrolytes. Such separated tank volumes may comprise four separate tanks or two tanks with dividers.

In some embodiments, a flow battery stack assembly 106 may comprise a plurality of electrochemical reaction cells configured for charging and discharging active species in the liquid electrolytes. Pumps 108 may be provided to pump electrolytes through the flow battery stack assembly 106 and any other connected systems, such as a rebalancing system 110 and/or an electrolyte concentration monitoring system 100. In some embodiments, the redox flow battery system 102 may be electrically connected to a power source 112 and/or an electric load 114. An electronic controller 116 may also be provided to control the operation of the redox flow battery system 102, including the operation of pumps, valves, electrical connections, or any other electronic or electromechanical component within the redox flow battery system 102.

### Iron/Chromium Flow Battery Electrochemistry

The valence state of the Fe and Cr ionic species in an Fe/Cr flow battery changes between charge and discharge. Information on the concentration of the ionic species may be needed to determine the state-of-charge (SOC) of the battery and the electrolyte balance of the anolyte and catholyte. In some embodiments, the electric potential of an Fe/Cr flow battery cell may be used to monitor the SOC of the battery. A higher voltage suggests that the battery SOC is higher. However, the voltage of a flow battery cell may be ambiguous in that there are four ionic species in an Fe/Cr flow battery (Cr²⁺, Cr³⁺, Fe³⁺ and Fe²⁺) that contribute to the cell voltage. In some embodiments, a more definitive measure of the SOC and concentration of the ionic species may be obtained by measuring the voltage of the anolyte and catholyte separately.

If charge and discharge are perfectly reversible, the cell is always in balance, with the same concentration of Fe³⁺ in the catholyte as Cr²⁺ in the anolyte. In reality, side reactions typically make the concentration of Fe³⁺ in the catholyte higher than that of Cr²⁺ in the anolyte. In this state, the system is said to be unbalanced and the energy storage capacity of the battery decreases. An unbalanced system must be appropriately rebalanced to regain the energy storage capacity. Insufficient rebalancing still leaves more Fe³⁺ in the catholyte than Cr²⁺ in the anolyte, leading to a condition that will be referred to herein as positive imbalance. Excessive rebalancing results in less Fe³⁺ than Cr²⁺ in the catholyte and anolyte respectively, leading to a condition that will be referred to herein as negative imbalance. In either case, the capacity of the cell is not fully regained.

In an ideal Fe/Cr redox flow battery, the overall electrochemical reaction during charging is:

Fe²⁺+Cr³⁺→Fe³⁺+Cr²⁺ [3]

The Nernst equation gives the relationship between cell electric potential and electrolyte concentration.

E_{cell}=E⁰+(RT/nF)*ln([Fe³⁺][Cr²⁺]/[Fe²⁺][Cr³⁺]) [4]

In some embodiments, if the cell does not suffer from H₂ evolution or other side reactions, then the concentrations of Fe³⁺ and Cr²⁺ may be equal, and may be determined from the cell potential. However, with side reactions, the SOO of both catholyte and anolyte cannot be determined from cell potential measurement. To avoid issues related to the cell potential, separated half-cell redox potential measurements of the anolyte and catholyte may be made to determine the SOO of each electrolyte independently. Measuring the redox potential of the electrolyte may be carried out by using a reference electrode and an indicating electrode. Any suitable reference electrode, such as a calomel electrode or a silver-silver/chloride (Ag/AgCl) electrode may be used. Embodiments of suitable indicating electrodes include platinum, gold or carbon electrodes among others. These electrodes are all commercially available from Sensorex, for example.

In a measurement arrangement using both an indicating electrode and a reference electrode, the potential of the reference electrode is the same regardless of the concentration of various species in solution. But the potential of the indicating electrode varies linearly according to Ln([Fe³⁺]/[Fe²⁺]) in the catholyte, and Ln([Cr²⁺]/[Cr³⁺]) in the anolyte. However, measurements obtained using reference electrodes in a redox flow battery are subject to several sources of error and may be subject to measurement uncertainty on the order of 10 mV or more.

### Monitoring Electrolyte Concentrations

To control a rebalancing reaction so that it proceeds to the correct extent, it is desirable to know the concentrations of the charged form of the active species in the electrolytes (e.g., Fe³⁺ in the catholyte and Cr²⁺ in the anolyte). It may be sufficient in some embodiments to know the difference between the concentration of Fe³⁺ in catholyte, and that of Cr²⁺ in the anolyte. A very small, ideally zero, difference is usually desired.

Various techniques for monitoring the concentrations of reactants dissolved in liquid electrolyte are available, including measuring properties of the electrolyte such as redox potential, refractive index, density, concentration (e.g. by spectroscopic analysis) or various combinations of these.

Conventionally, the state of the charge of a redox system may be determined using a separate Open Circuit Voltage (OCV) cell, as described by Hagedorn and Thaller (NASA/TM-81464). The OCV cell may be structurally similar to a flow battery cell except that an OCV cell may have a very high impedance across the electrodes. Voltage is measured across this resistance, and as the current is virtually zero, it is very close to the OCV, which in turn is directly related to the concentrations of the reactants through Nernst Equation as described above. Measurement of the OCV is therefore an indirect measurement of the ratio of reactants in the system. However, measuring only the OCV in order to determine the charge balance of the redox system has substantial limitations. For example, it is difficult to distinguish a partially discharged system from a system that is out of balance due to parasitic side reactions. To overcome this limitation a count of the coulombs of energy introduced into the electrolytes during charging and withdrawn from the electrolytes during discharging may be performed, such as by using an accurate coulomb gauge. However, such a coulomb gauge may also be subject to cumulative error after many cycles of operation due to factors such as parasitic side reactions, undesired diffusion and migration of reactant species, electrolyte cross-over and other phenomena. The presence of internal shunt currents generated through conductive liquid paths across cells further complicates coulomb-counting in a full redox system.

Many other factors and phenomena may also complicate measurement of flow battery charge state based on OCV measurement. For example, in redox systems based on mixed reactant chemistry, it becomes even more difficult to measure the state of charge and state of balance by measuring only the OCV, as there are many reactants and unknown concentrations involved in the Nernst Equation. Even when reactants are unmixed, cross-diffusion renders the calculation of state of charge and state of balance from OCV erroneous. Various examples of systems and methods configured to leverage similar fundamental principles while overcoming the shortcomings described above are described herein.

### Test Cell Structure

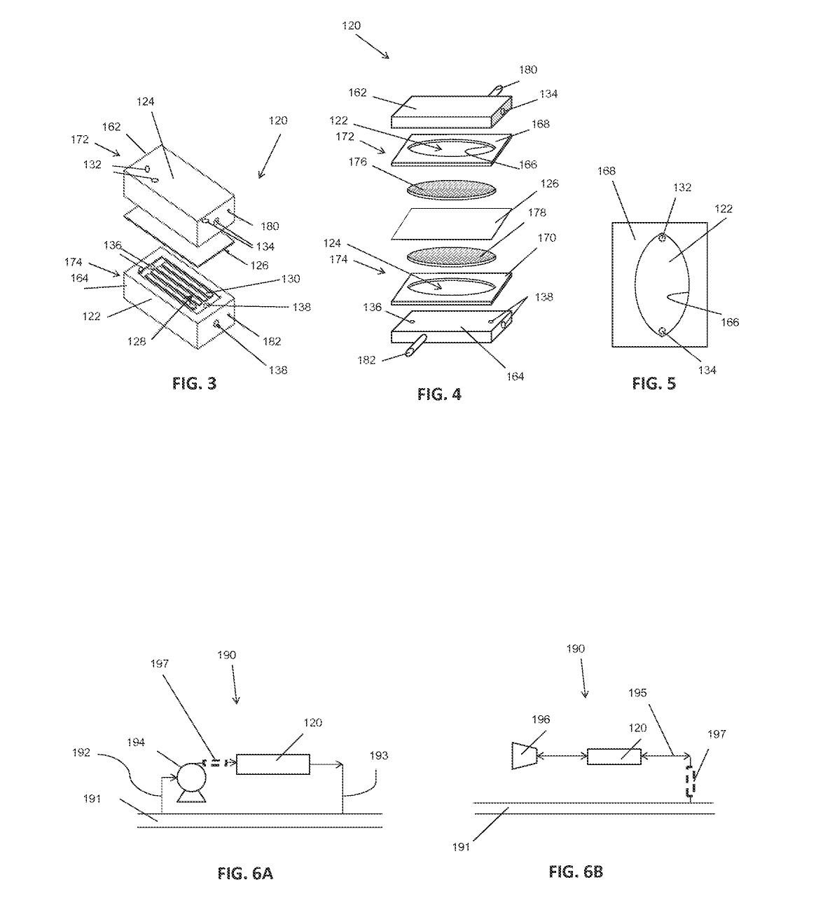

In some embodiments, SOO and/or imbalance of electrolytes may be measured by placing electrolytes within a suitably configured test cell and monitoring changes in voltage, current, or other electrical quantities over time. A cross-sectional view of one embodiment of a test cell 120 is shown in FIG. 2. As shown in FIG. 2, some embodiments of a test cell 120 may comprise first and second electrolyte chambers 122, 124 with a separator membrane 126 in between. In some embodiments, each chamber 122, 124 may be substantially occupied by a porous, conductive material such as a carbon or graphite felt material. In alternative embodiments as illustrated in FIG. 3, the first and second electrolyte chambers 122, 124 may include shallow flow channels 128 separated by ribs 130 or any other structure configured to conduct electrons to and from the liquid electrolyte.

As shown in FIG. 2, the first electrolyte chamber 122 may include fluidic ports 132, 134 and the second electrolyte chamber 124 may include fluidic ports 136, 138, respectively, through which electrolyte may flow into and/or out of the respective electrolyte chamber 122, 124. In some embodiments, a pair of the fluidic ports 134, 138 may be joined by a fluid path 140 in fluid communication with one another such that electrolyte may be directed first as indicated at arrow 142 into the first electrolyte chamber 122 through fluidic port 132, out of the first electrolyte chamber 122 second through fluidic port 134 through fluid path 140, and third into the second electrolyte chamber 124 via fluidic port 138 before fourth exiting the test cell 120 via fluidic port 136 as indicated at arrow 144 in the second electrolyte chamber 124.

In alternative embodiments, electrolyte as indicated by arrows 146, 148 may be directed separately and in parallel respectively into fluidic ports 132, 136 and then out of fluidic ports 134, 138 as indicated by arrows 146, 148. Fluidic ports 132, 134, 136, 138 may take any form and may be any shape and size as desired to deliver electrolyte into and out of the electrolyte chambers 122, 124 of test cell 120.

In some embodiments, one or both electrolyte chambers 122, 124 may contain porous electrodes of carbon felt or other suitable flow-through electrode material. For example, any material that is conductive and inert in the electrolyte may be used as a porous or solid electrode that may be placed within or formed integrally with a portion of one or both cell chambers. In some embodiments, a surface of one or both electrodes may treated, plated or otherwise coated with a catalyst material selected to promote desired reactions or to suppress undesired reactions. A test cell 120 may also include electrical terminals 180, 182 for electrically connecting the test cell 120 to a power source or electric load 156. The test cell 120 may include one or more bipolar plates or terminal plates 158, 160 in contact with an electrode within the electrolyte chambers 122, 124, respectively.

FIGS. 3-4 illustrate exploded views of two embodiments of test cells 120. With particular reference to FIG. 4, a test cell 120 may comprise an upper body portion 162 and a lower body portion 164 that may be clamped, bolted, welded or otherwise sealed together, sandwiching a separator membrane 126 and any other desired components therebetween. In embodiments of a test cell 120 such as that shown in FIG. 4, the electrolyte chambers 122, 124 may be defined by cutouts 166 in a pair of removable chamber layers 168, 170. In some embodiments, the chamber layers 168, 170 may be made of a compressible gasket material, such as rubber or silicone. In other embodiments, chamber layers 168, 170 may be made of any other desired material, such as plastics or solid graphite. In some embodiments, chamber layers 168, 170 may be adhered to respective upper and lower body portions 162, 164. In other embodiments, chamber cavities may be machined, cast, molded or otherwise formed directly into the upper and lower body portions 162, 164, such as depicted in FIG. 3.

In some embodiments, the upper and lower body portions 162, 164 may be made of graphite, thus allowing upper and lower cell body halves 172, 174 themselves to be used as electrodes to measure the voltage of the test cell 120. In other embodiments, the upper and lower body portions 162, 164 may be made of any other material, electrical contact may be made with porous or other electrodes within the electrolyte chambers 122, 124. For example, the embodiment shown in FIG. 4 may include porous carbon felt electrodes 176, 178 configured to occupy the electrolyte chambers 122, 124.

In some embodiments, electrical terminals 180, 182 may be provided in electrical connection with each electrolyte chamber 122, 124. In some embodiments, if the entire cell body is conductive, the electrical terminals 180, 182 may be connected to the exterior of the cell body. Electrical terminals 180, 182 may be made of any suitable electrically conductive material. In some embodiments, each cell body half 172, 174 may comprise more than one electrode for measurement, charging, discharging or other purposes as will be described in further detail below.

As shown in FIG. 5, in some embodiments, the electrolyte chamber 122 may comprise an almond (or pointed oval) shape. The almond shape may facilitate flow conditions that may substantially prevent stagnation regions within the chamber 122 during flushing and filling of the test cell 120. In alternative embodiments, other chamber shapes may also be used

In some embodiments, the volumes of the electrolyte chambers 122, 124 in a test cell 120 may be very small in order to shorten the measurement time. In some embodiments, the volumes of the two electrolyte chambers 122, 124 may be substantially equal to one another. The volume of each electrolyte chamber 122, 124 may be less than about 1 mL in some embodiments. In one particular embodiment, the volume of each electrolyte chamber 122, 124 may be about 0.8 mL. In other embodiments, the electrolyte chambers of a test cell may be larger or smaller as desired.

In some embodiments as shown in FIG. 3, ribs 130 in the electrolyte chambers 122, 124 may be used to further minimize electrolyte volume and/or to maintain the position of the separator membrane 126 such that the volumes of electrolyte in the two cell body halves 172, 174 are substantially the same. However, equal electrolyte volumes in the test cell 120 are not necessary in all embodiments. In some embodiments ribs 130 may be included in an almond-shaped electrolyte chamber. One function of the ribs 130 may be to increase reaction surface area and to decrease the distance that an ion has to diffuse to reach the electrode surface.

In some embodiments the separator membrane 126 of the test cell 120 may be of a porous material. In other embodiments, the separator membrane 126 may be an ion selective membrane, such as a cation exchange membrane or an anion exchange membrane. In some embodiments, the selection of the porosity and/or selectivity of a separator membrane 126 may depend on the active materials under evaluation among other factors.

In some embodiments, an electrolyte concentration monitoring system 100 for detecting an imbalance such as those described herein may be provided as a stand-alone system configured to be independent of any redox flow battery system 102. In other embodiments, an electrolyte concentration monitoring system 100 may be integrated into a redox flow battery system 102 as shown for example in FIG. 1. Various embodiments of flow-battery-integrated monitoring systems may be configured with different fluid delivery arrangements.

In some embodiments, a fluid delivery apparatus 190 may be provided to direct liquid electrolytes from a flow battery into the test cell 120. As shown in FIG. 1, in some embodiments a test cell 120 may be joined in fluid communication with electrolyte conduits 184, 186 downstream from electrolyte pumps 108. In such embodiments, valves 188, 189 may be provided to selectively direct electrolytes through the test cell 120 during normal pumping of electrolytes through the flow battery system 102. In alternative embodiments, fluidic connections for filling a test cell 120 may be independent of battery pumping apparatus. In some embodiments, a test cell fluid delivery apparatus may be configured to pump electrolytes directly from the tanks 104 into the test cell 120.

In some embodiments, a fluid delivery apparatus 190 may be configured to fill a test cell 120 by parallel flow as shown by the solid arrows 146, 148 in FIG. 2. In parallel filling, both electrolyte chambers 122, 124 may be filled substantially simultaneously, with electrolyte exiting the electrolyte chambers separately as indicated by solid arrows 146, 148. Alternatively, in some embodiments, if equal volume of the two electrolytes are mixed, the test cell halves may be filled with the neutralized electrolyte in series as illustrated by the dashed arrows 142, 140, 144 in FIG. 2. During series filling, both electrolyte chambers 122, 124 may be filled in series by directing an outlet (fluidic port 134) of the first electrolyte chamber 122 into an inlet (fluidic port 138) of the second electrolyte chamber 124. A parallel filling arrangement may provide lower flow resistance, while a series filling arrangement may provide improved assurance of electrolyte flow through both electrolyte chambers 122, 224.

In some embodiments of a fluid delivery apparatus 190 as shown in FIG. 6A, the test cell 120 may be arranged in a through-flow configuration relative to an electrolyte flow conduit 191. In a through-flow configuration, the test cell 120 may include separate inlet and outlet flow lines 192, 193, both of which may be joined to an electrolyte flow conduit 191. In some embodiments, a flow-through arrangement may include one or more pumps 194 to pull electrolyte from the electrolyte conduit and to push electrolyte through the test cell. Any type of pump may be used.

In some alternative embodiments, as shown for example in FIG. 6B, the test cell 120 may be arranged in a reciprocating flow arrangement relative to an electrolyte flow conduit 191. In a reciprocating flow arrangement, the electrolyte may be taken from one point in an electrolyte conduit 191 and returned to the same point via reciprocating flow line 195. In a reciprocating flow arrangement, a reciprocating pump 196, such as a syringe pump may be used. In some embodiments, the stroke volume of a syringe pump may be substantially larger than the volume of the cell chambers and the tubing combined to ensure that the cell will be completely filled with fresh electrolyte. FIGS. 6A-6B illustrate only one electrolyte flow channel for simplicity of illustration.

In some embodiments, in combination with any of the above-described fluidic arrangements, it may be desirable to mix positive and negative electrolytes prior to directing the neutralized electrolyte solution into the test cell 120. In such embodiments, an electrolyte mixing device 197 may be included to mix electrolytes prior to injecting neutralized electrolyte into the test cell 120. In some embodiments, an electrolyte mixing device may simply comprise a common section of electrolyte conduit. In other embodiments, electrolyte mixing devices 197 used in connection with a test cell filling apparatus may include any static or dynamic mixing device. In some embodiments, an electrolyte mixing device 197 may comprise a static mixer device such as those produced by Koflo Corp. (http://www.koflo.com/). In other embodiments, other static mixing structures, dynamic mixer bars or other mixing devices or structures may be used.

In some embodiments, an electrolyte concentration monitoring system 100 may include an electronic module 198 as shown for example in FIG. 1. An electronic module 198 may be configured to deliver an electrical current to the test cell in order to discharge and/or charge the electrolyte within the test cell 120 as described in more detail below. The electronic module 198 may also be configured to measure the open-circuit voltage (OCV) and/or the closed-circuit voltage (CCV) of the test cell at regular periodic time intervals. In some embodiments, an electronic module 198 may also be configured to control valves and/or a pump for filling the test cell 120. In further embodiments, an electronic module 198 may be configured to control an active mixing device or any other electronic or electromechanical component within the electrolyte monitoring system. An electronic module 198 may be electrically connected to the test cell 120 at electric terminals 180, 182 (e.g. in FIG. 3 and FIG. 4).

In some embodiments, an electronic module 198 may comprise an analog circuit and a micro-computer controller. In some embodiments, the analog circuit may comprise a controlled current source and a signal conditioning circuit for reading voltages.

In some embodiments, a micro-computer controller may comprise one or more analog input channels to measure OCV or potential and at least one digital input channel for operator interfacing. In some embodiments, a micro-computer controller may also comprise a plurality of digital output channels to control pumps, valves and/or other electromechanical components. A micro-computer controller may also comprise at least one communication port, such as an industrial standard RS232 or USB port, in order to allow for communication between the electronic module 198 and a main flow battery system controller 116. Examples of suitable micro-computer controllers include: the open source ARDUINO architecture (http://arduino.cc), TEENSY (http://pjrc.com/teensy), and BASIC STAMP (http://parallax.com). Any other suitable micro-computer controller may also be used. Alternatively, all functions of the electronic module 198 may be incorporated into components within the main flow battery system controller 116.

In some embodiments, an electronic module 198 of an imbalance and/or concentration monitoring system 100 may be controlled by the main flow battery system controller 116. In some embodiments, the electronic module may be configured with two states, “stand-by” and “busy.”

An example of an interaction between a flow battery system controller 116 and an electronic module may include the following steps: (1) The system controller 116 determines that the electronic module 198 is in standby mode, and then sends a command to the electronic module to begin a specified measurement process. (2) The electronic module 198 acknowledges receiving the command, and changes its state to “busy”. (3) The electronic module may then execute steps to carry out the specified measurement process. (4) On completion of the measurement process, the electronic module 198 may perform data reduction steps, and may transmit data back to the main system controller 116. (5) The electronic module may then return to “standby” mode, at which point it stands ready to receive commands from the main system controller 116 to begin a new measurement process. Examples of various embodiments of measurement processes will now be described.

### Coulometric Monitoring Methods

As discussed above, conventional methods of determining charge imbalance, SOO or SOC using coulometry are insufficient for the reasons described above. However, Applicants have developed systems and methods that control or reduce the uncertainties described above in order to leverage principals of coulometry to determine an electrolyte charge imbalance state, and/or a state-of-oxidation of one or both electrolytes. Some of these methods and systems benefit from an ability to recognize a familiar point during a charge or discharge cycle at which assumptions can be made regarding a charge state of one or both electrolytes.

In some embodiments, the degree of imbalance of flow battery electrolytes (or the concentration of electrolyte reactants) may be measured by methods based on the concept of coulometric titration. Such methods are collectively referred to herein as coulometric methods. In some embodiments, coulometric methods of characterizing electrolyte reactant concentrations may generally benefit from mathematical relationships between charging or discharging time and electrolyte reactant concentrations as described below.

Various embodiments of coulometric methods may generally include placing approximately equal volumes of neutralized electrolyte (i.e. an electrolyte solution obtained by mixing together or substantially entirely discharging approximately equal volumes of positive and negative electrolyte) into the test cell and then applying a charging current to the test cell while monitoring test cell voltage. As will be described in further detail below, the degree of imbalance of the electrolytes may be determined by measuring the time that elapses between the moment a known charging current is initiated until a pre-determined stop-point (e.g., a pre-determined voltage) is reached.

In some embodiments, neutralized electrolyte may be obtained by mixing substantially equal volumes of the anolyte and catholyte. When equal volumes of the positive and the negative electrolyte are mixed, the SOO of the resultant electrolyte is the average of the two individual electrolytes. In some embodiments, mixing of electrolytes may be performed in a vessel or flow channel prior to injecting the mixed (neutralized) electrolyte solution into a test cell. Alternatively, any of the mixing devices described above or equivalents thereof may be used.

Thus, in some embodiments, equal volumes of positive and negative electrolyte may be mixed together and the neutralized electrolyte may be injected into the two sides of a test cell. In such embodiments, after injecting electrolytes into the test cell, the same neutralized electrolyte solution will be present in both half-cell chambers of the test cell.

In alternative embodiments, neutralized electrolyte may be obtained by electrochemically discharging the electrolytes without necessarily mixing them in a batch process. In these alternative embodiments, instead of mixing the electrolytes, some volume of the positive electrolyte may be pumped through one electrolyte chamber 122 (FIG. 2) of the test cell 120, and some volume of the negative electrolyte may be pumped through the other electrolyte chamber 124 of the test cell 120. The volumes of positive and negative electrolytes pumped through the test cell 120 need not be equal. In some embodiments, the volumes of electrolytes pumped through the test cell 120 may be in excess of the volume of the respective half-cell compartments (electrolyte chambers 122, 124) so as to ensure that any excess liquid from previous tests is flushed out of the electrolyte chambers 122, 124.

In some embodiments, the electrolytes may then be discharged by short-circuiting the test cell 120, such as by electrically connecting the terminals 180, 182 of the two cell body halves 172, 174. In some embodiments, the test cell 120 may be connected to an electric load. The electrolytes in the electrolyte chambers 122, 124 may be discharged until eventually the test cell 120 reaches an open circuit voltage of approximately 0V. At this point, the electrolytes in the two cell body halves 172, 174 of the test cell 120 will be chemically the same as they would be if the electrolytes had been directly mixed in equal volumes. In other words, after discharging the test cell 120, the electrolyte in both electrolyte chambers 122, 124 will have an SOO that is the average of the two individual electrolytes.

In some cases, allowing the test cell 120 to discharge by a short circuit may take an undesirably long time. Thus, in some embodiments, the test cell 120 may be discharged by applying a discharge current. In some embodiments, a discharge current may be applied by repeatedly passing short-duration electric current pulses through the test cell 120 while regularly checking open-circuit-voltage of the test cell 120 in between current pulses. The pulsed-current discharge process may continue until the voltage measurement indicates that the test cell 120 has been discharged substantially to zero (or near enough to zero or less than about 0.002V in some embodiments). In some embodiments, an applied current of about 0.2 A or higher may be used as a discharge current. In some embodiments, a higher current may discharge the electrolytes in the test cell 120 faster, but higher currents may also require faster electronics to monitor changes in cell voltage. In other embodiments, smaller discharge currents may be desirable. Thus, in some embodiments, the applied current may depend on the size of the test cell, among other factors.

Once both electrolyte chambers 122, 124 of the test cell 120 contain neutralized electrolyte, a charging current may be applied to the test cell. The change in cell voltage may then be monitored over time until the test cell OCV or CCV reaches a pre-determined value (or until another stop-point is reached). The total charging time between initiating a charging current and the test cell 120 reaching the pre-determined end-point may be correlated to the degree of imbalance as described in further detail below.

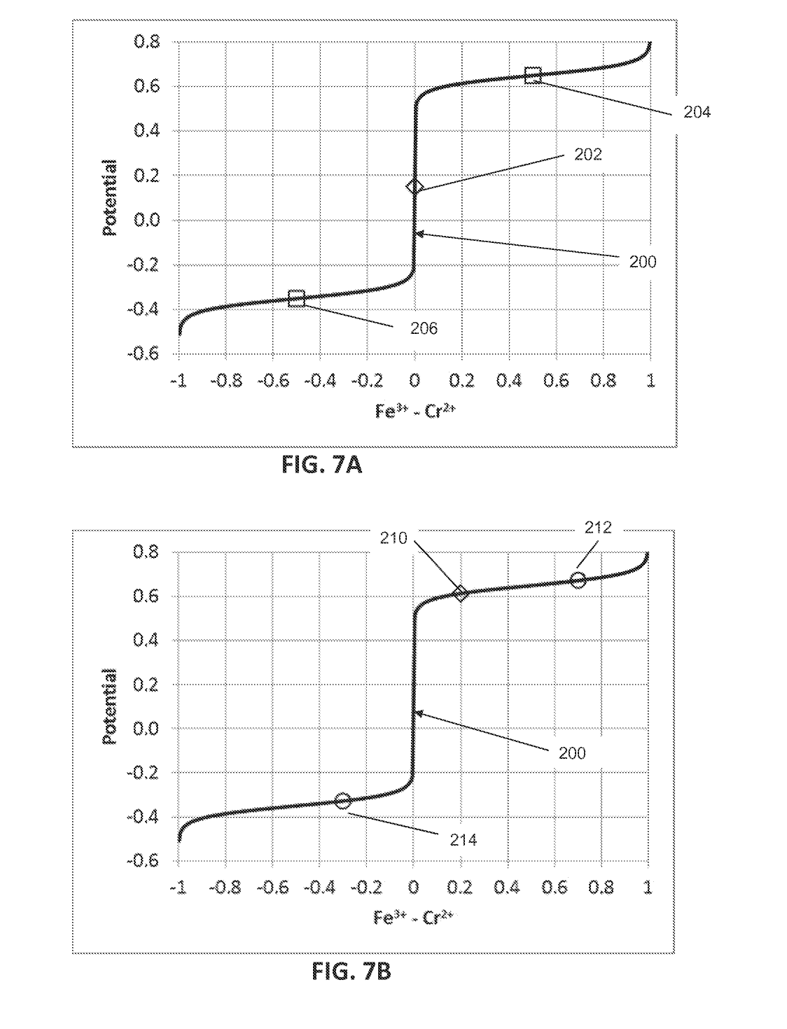

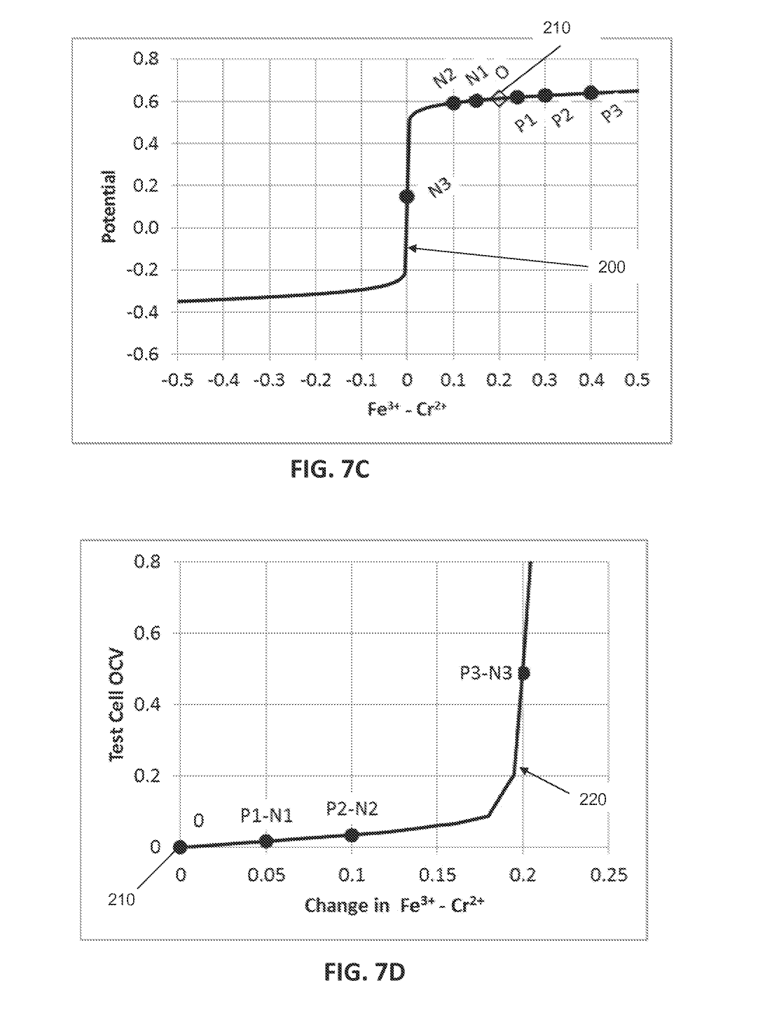

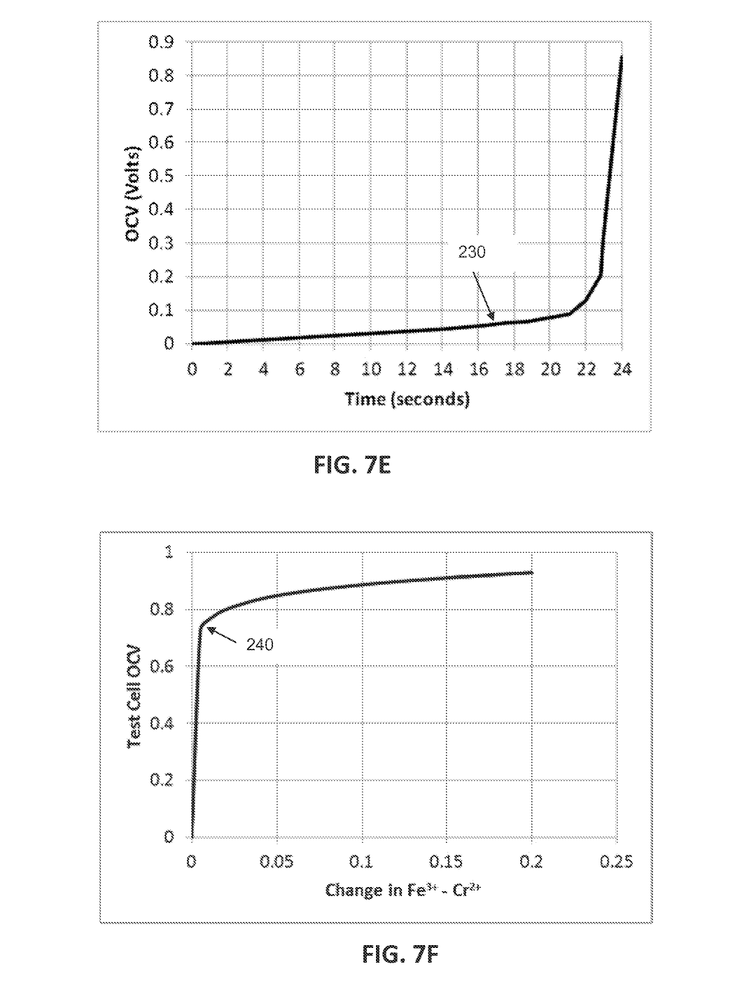

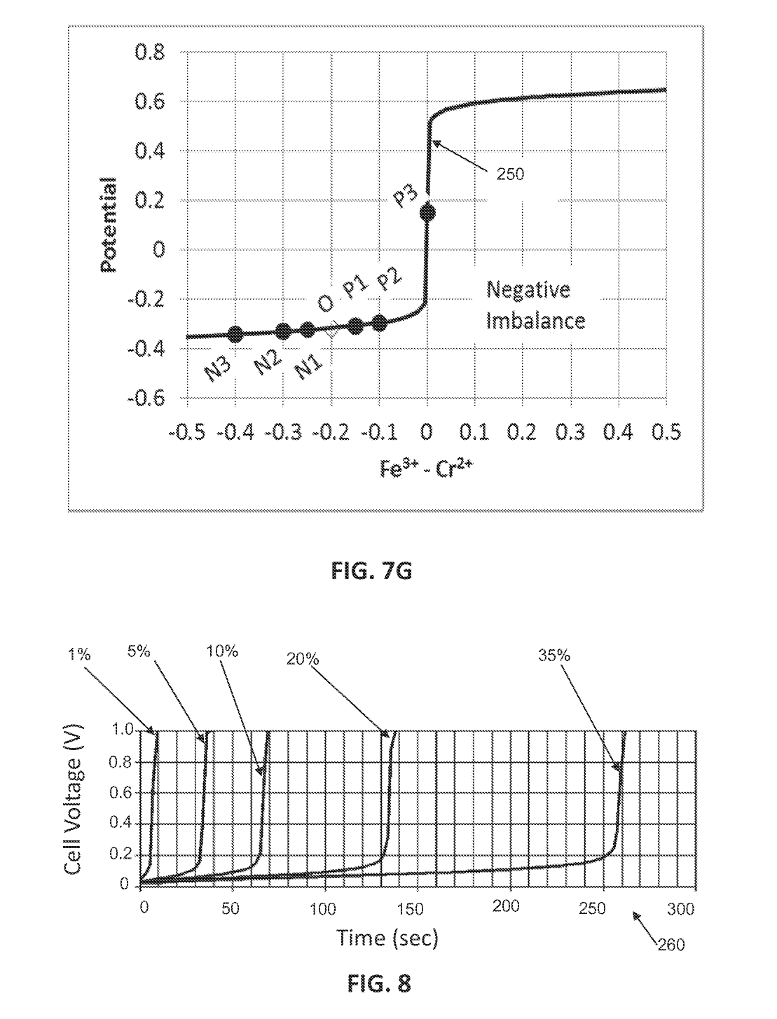

Embodiments of a coulometric imbalance measurement process for an Fe/Cr flow battery will now be described with reference to FIGS. 7A-7F. Although the following examples are given with reference to an Fe/Cr redox couple, the same principles will apply to substantially any other redox couple.

In the case of an Fe/Cr flow battery, the standard reduction potentials are:

e⁻+Fe³⁺→Fe²⁺ E^{o}_{Fe}=0.65V [5]

Cr³⁺→Cr²⁺+e⁻ E^{o}_{Cr}=−0.35V [6]

The potential of each electrolyte may be determined from the Nernst equation as a function of the ratio of un-charged to charged concentration. For example:

Catholyte: E_{Fe}=E^{o}_{Fe}+(RT/nF)Ln(Fe²⁺/Fe³⁺) [7]

Anolyte: E_{Cr}=E^{o}_{Cr}+(RT/nF)Ln(Cr²⁺/Cr³⁺) [8]

For the special case of a perfectly discharged electrolyte, the entire concentration of the active species will be in their discharged forms. As a result, the second term of the Nernst equations becomes undefined. In most such cases, the potential of each electrolyte is about half the sum of the standard redox potentials:

E=(E^{o}_{Fe}+E^{o}_{Cr})/2 [9]

Thus, by using equations [5]-[9], the theoretical potential at any state of oxidation may be calculated for a pair of flow battery electrolytes. The double-S shaped curve 200 of FIG. 7A-7C is a graph of electric potential vs. charged-species concentration difference (i.e. Fe³⁺=Cr²⁺) for an Fe/Cr redox couple. The examples of FIGS. 7A-7E assume that the total concentration of each active material is the same in both electrolytes (e.g., that total Fe=total Cr=1M). The corresponding graphs for embodiments with unequal total concentrates will be qualitatively similar, but the positive and negative plateaus will be of different widths.

The imbalance of the electrolytes may be defined in terms of concentration as the difference between the concentration of Fe³⁺ in the positive electrolyte and that of Cr²⁺ in the negative electrolyte. In a perfectly balanced system, the concentration of Fe³⁺ in the positive electrolyte is equal to the concentration of Cr²⁺ in the negative electrolyte, and the imbalance is zero. Thus, the horizontal axis of the charts in FIGS. 7A-7C may also be labeled “imbalance.”

FIGS. 7A-7D illustrate the theoretical relationship between electrolyte concentration difference (Fe³⁺−Cr²⁺) and electric potential (V) of the positive electrolyte (represented by positive values to the right of zero) and negative electrolyte (represented by negative values to the left of zero). If the electrolytes are balanced (and total Fe=total Cr), the concentration difference of the positive electrolyte will be equal in magnitude and opposite in sign to the concentration difference of the negative electrolyte.

When positive and negative electrolytes are neutralized (as described above), the catholyte concentration difference decreases (moves to the left) and the anolyte concentration difference increases (moves to the right), until the two concentration difference values meet at a point equal distance in x coordinate from the two original points. If the imbalance is zero, the final point is the midpoint of the double S curve 200, as indicated by the diamond 202 at the center of FIG. 7A. The diamond 202 also represents the midpoint between the starting SOO values of the anolyte and catholyte indicated by the squares 204, 206. The maximum slope of the double S curve 200 occurs at the point at which SOO=0.

As shown in FIG. 7B, when the imbalance is greater than zero (i.e. positive imbalance), the final point 210 after SOO-averaging the electrolytes is still an equal distance in x coordinates from the two original points 212, 214, but it is not the mid-point of the double S curve 200. As shown, the final point 210 for a neutral electrolyte of this positively unbalanced electrolyte is shifted to the right of zero on the double S curve 200. (If the electrolyte were negatively unbalanced by the same amount, the final point 210 would be shifted an equal distance to the left of zero on the curve 200). To test the degree of imbalance of this solution within a test cell 120, a charging current may be applied to the test cell 120. At this point, the solution in the positive chamber of the test cell 120 becomes representative of the catholyte, and the solution in the negative chamber of the test cell becomes representative of the anolyte.

As the test cell 120 is charged, the cell voltage (which is the difference between the positive electrolyte potential and the electrolyte negative potential) will increase as the positive electrolyte concentration difference moves to the right and the negative concentration difference moves to the left from the midpoint (final point 210) along the double S curve 200. As shown in FIG. 7C, as the test cell 120 is charged, the catholyte concentration difference increases from point P1 to point P2 to point P3, while the anolyte concentration difference decreases from point N1 to point N2 to point N3. As the concentration difference values move through these points, the test cell OCV will remain close to zero for a period of time, and will then rise sharply as the concentration difference of the negative electrolyte approaches zero. In some embodiments, this point (i.e. the point at which the concentration difference of the negative electrolyte is substantially equal to zero) is the point at which the time measurement should be stopped, since this is the point at which all the excess charged reactant species in the neutralized electrolyte has been converted (i.e., oxidized or reduced) to its discharged form (e.g., all Fe³⁺ has been reduced to Fe²⁺). Methods of identifying this end-point during measurement will be described in more detail below.

As shown in FIG. 7D, the slope of the OCV versus change in concentration difference curve 220 dramatically increases at about the point representing an excess Fe³⁺ concentration of 0.2. The slope of the OCV versus time curve 230 will be similarly shaped in FIG. 7E, and will reach a maximum at the point that corresponds to one of the electrolyte concentration differences passing through zero in the double S curve 200 of FIGS. 7A-7C.

By contrast, FIG. 7F illustrates an OCV versus change in concentration difference curve 240 for the balanced electrolyte of FIG. 7A. In this case, because the starting concentration difference is zero, the cell potential immediately increases dramatically before the slope decreases as the charged species concentrations depart from zero.

FIG. 7G is a graph 250 of electrolyte potential versus concentration difference for an Fe/Cr flow battery system, with points illustrating a negatively unbalanced electrolyte solution.

When a pre-determined end-point is reached, the charging may be stopped, and the total charge time may be determined. In some embodiments, the cell may be charged by alternately applying charge current pulses and switching off the charging current to measure OCV. For example, in some embodiments, a pulsed charging current may be cycled between applying a current for 0.4 second and switching off the current for 0.1 second. In such an example, a charging current is applied for eight tenths (80%) of each second. Thus, a total charge time may be obtained by multiplying a total elapsed time (i.e., the time between initiating a charge and reaching an end-point) by the proportion of time during which current is applied (i.e., 80% in the above example).

Charging the cell at a known current for a measured amount of time (t) in seconds, the cumulative quantity of charge (i.e., the number of Coulombs, ‘C’) introduced into the electrolytes may be calculated based on the definition of electric current (I):

C=t*I [10]

The number of moles (‘n’) of charged electrolyte species corresponding to the cumulative charge may be obtained by dividing the charge by the Faraday constant (‘F’):

n=C/F [11]

This provides the number of moles of the excess charged electrolyte species in the neutralized electrolyte. Because the selected measurement end-point ideally represents the point at which the non-excess electrolyte concentration difference is zero, the number of moles calculated in equation [11.] represents the number of moles of excess charged ions in the neutralized electrolyte. Dividing n by the known volume of one test cell chamber provides the molar concentration (M) of the excess species in the neutralized electrolyte. The imbalance of the system is the difference between Fe³⁺ in the catholyte and Cr²⁺ in the anolyte. This is twice the amount of the excess species in the final neutralized electrolyte. Therefore the system imbalance is twice the molar concentration of the excess species.

FIG. 8 illustrates a graph 260 of several examples of test cell voltage versus time relationships using samples with known excess concentrations of Fe³⁺/Cr²⁺ in a prototype test cell. The voltage versus time and voltage versus SOO change relationships will vary depending on specific characteristics of the test cell, including the cell's electrical resistance, the volume of the electrolyte chambers, the type of separator membrane used, and other factors.

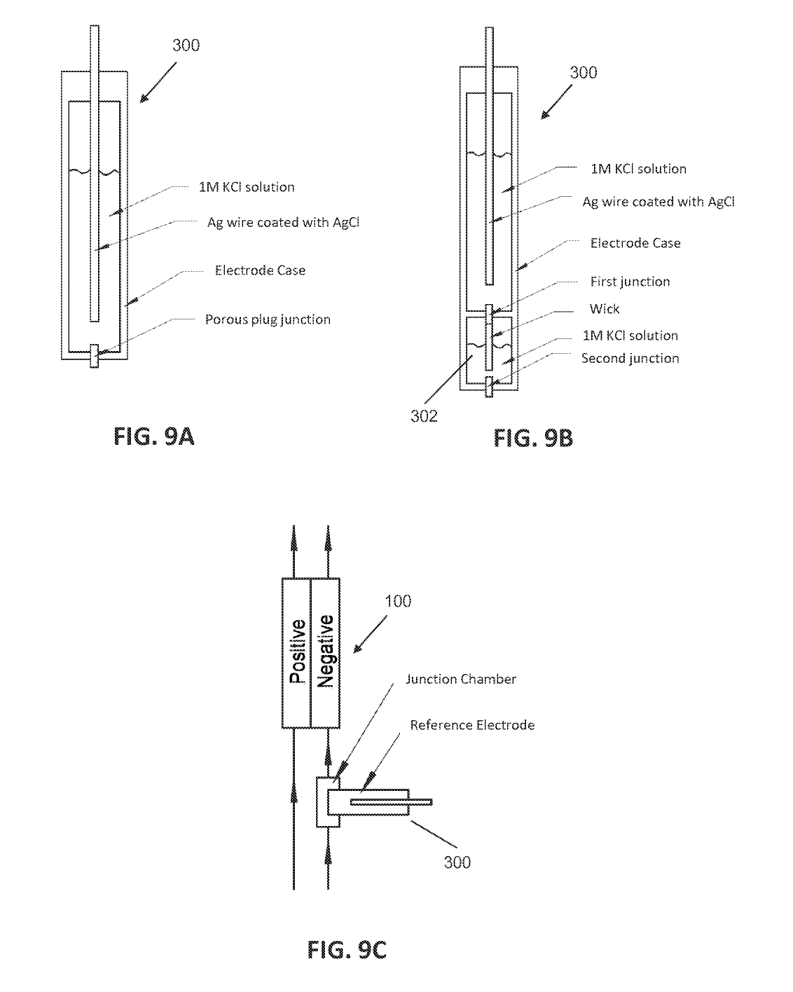

In some embodiments, a reference electrode may be useful in distinguishing positive imbalance in which [Fe³⁺]>[Cr²⁺] from negative imbalance in which [Cr²⁺]>[Fe³⁺]. A practical reference electrode 300 as shown in FIGS. 9A-9B typically has its own internal solution, the concentration of which remains constant. This gives a constant potential of the reference electrode 300. The internal solution may be placed in contact with a sample electrolyte 302 through a junction made of a porous material, as shown for example in FIG. 9B.

Some reference electrodes may not be stable in long term contact with liquid electrolytes because the electrolyte being measured can leak into the reference electrode chamber and mix with the reference electrode's internal solution, thereby degrading the accuracy of the measurement. In some embodiments, a reference electrode for long-term use in a redox flow battery electrolyte may be constructed with features designed to limit the rate of migration of electrolyte liquid into the internal solution of the reference electrode. In general, such features may include a leak path that is relatively long and/or has a relatively small cross-sectional area. Additionally, well-sealed chambers may be further beneficial.

In FIG. 9C, a reference electrode 300 may be incorporated with an imbalance or electrolyte concentration monitoring system test cell 100 such as those described herein by placing the reference electrode in contact with at least one electrolyte somewhere in the flow path. In some embodiments, the point of contact does not need to be inside the imbalance test cell (although, it may be), and may be either in the flow path of the catholyte or the anolyte, either up-stream or down-stream from the cell.

In some embodiments, measurement of the potential of either the positive or the negative electrolyte may be made with respect to the reference electrode. The value of such a measurement may unambiguously determine whether the system has positive or negative imbalance. Although measurement with a reference electrode is not highly accurate, and may be subject to an uncertainty on the order of 10 mV, such uncertainty does not affect the use of the reference electrode for this purpose. This is because the cases of positive and negative imbalance give very different potential of the neutralized electrolyte. Because the middle section of the double S curve is very steep, a small difference in concentration corresponds to a large difference in OCV. For example, a positive imbalance of +0.005 M and a negative imbalance of −0.005 M results in about 0.7V difference in the potential.

With the internal solution of the reference electrode in contact with the test electrolyte through a porous junction, the chemical species in the test electrolyte will diffuse into the internal solution of the reference electrode over time, negatively affecting its accuracy. This may be greatly delayed by using reference electrode with multiple junctions, as shown in FIG. 9B. In some embodiments, a reference electrode with three or more junctions may also be used.

In various embodiments, the pre-determined end-point at which the time measurement is stopped may be based on different parameters. In some embodiments, the end point may be a voltage value may be based on a pre-determined value of either the closed circuit voltage (CCV) or open circuit voltage (OCV) of the cell. If CCV is used as the criterion, the charging current may be applied and CCV may be measured continuously. This may simplify the electronic module. If OCV is used as the criterion, the end point may be sharper and the accuracy may be improved, but the charging current must be applied in a pulsed manner such that OCV may be measured at regular intervals.

In some embodiments, a pre-determined end-point cell voltage (OCV or CCV) may be determined based on the known theoretical relationship between voltage and electrolyte concentration as shown and described above with reference to FIGS. 7A-7F. For example, as shown in FIG. 7D when change in Fe³⁺−Cr²⁺ is near 0.2M, the test cell OCV changes sharply. This indicates that 0.2M is the end point. In some embodiments, an end-point voltage may be at least 0.5V. In some particular embodiments, an end-point voltage may be about 0.55V, 0.65V or about 0.7V. In some embodiments, the ideal end-point voltage may change over time due to changing resistance of the test cell. Such changes may be identified by calibration and appropriate adjustments to end-point voltage or other adjustments may be made. Different end-point voltage values may be implied by voltage/concentration curves for different redox couples.

In other embodiments, a time measurement end-point may be based on a point at which the slope of the measured voltage vs. time curve reaches a maximum. For example, in some embodiments, measurement data (e.g., OCV and elapsed time) may be sampled and stored in a digital memory during a single test. Such measurement data may be analyzed by a processor to identify a maximum voltage vs. time slope. In some embodiments, the maximum slope may only be identifiable after it has passed. In such embodiments, the end-point time may be identified and applied retroactively.

In some embodiments, both a threshold voltage and a peak slope may be used to identify a measurement time end-point. For example, in some embodiments a processor may begin analyzing data to identify a maximum voltage vs. time slope only after a threshold voltage has been reached. In other embodiments, the calculation of a maximum slope may utilize other related quantities, such as voltage versus coulombs or others.

In some embodiments, a coulometric monitoring method may comprise the following operations: (1) Mix equal volumes (e.g. about 5 mL each in one embodiment) of positive and negative electrolyte; (2) Fill both chambers of the test cell with the neutralized electrolyte solution, flushing out any previously-present liquid from the test cell; (3) Apply a charging current to the test cell (e.g. about 0.2 A in one embodiment); and (4) Measure time until the voltage of the test cell reaches a desired set point (e.g. about 0.6 V in one embodiment). (5) Calculate a degree of electrolyte imbalance based on the coulombs of charge transferred to the electrolyte. Alternatively, Step (4) may comprise measuring time until the slope of a voltage versus time curve reaches a maximum or exceeds a pre-determined threshold.

In alternative embodiments, a coulometric monitoring method may comprise the following steps: (1) Fill each chamber of the test cell with a respective positive or negative electrolyte; (2) Discharge the test cell to approximately zero volts (e.g. by a short-circuit, by connecting a load, or by applying a pulsed discharge current); (3) Apply a charging current to the test cell (e.g. about 0.2 A in one embodiment); and (4) Measure time until the voltage of the test cell reaches a desired set point (e.g. about 0.6 V in one embodiment). (5) Calculate a degree of electrolyte imbalance based on the coulombs of charge transferred to the electrolyte. Alternatively, Step (4) may comprise measuring time until the slope of a voltage versus time curve reaches a maximum or exceeds a pre-determined threshold.

In some embodiments, the system may be calibrated using these steps with electrolytes of a known imbalance. For example, an electrolyte solution may be prepared with concentrations of total active materials identical to a flow battery system to be monitored. Such a solution may be prepared with a known excess quantity of one charged active species (e.g., with a known unbalanced ratio of Fe³⁺ to Cr²⁺). Alternatively, only one standard solution may be used to avoid difficulties in creating the neutralized electrolyte that is made by mixing two electrolytes and in keeping a Cr²⁺ solution with an accurate concentration. By testing such a known imbalanced electrolyte in a test cell, the test cell may be calibrated by applying a calibration constant to correct any systematic error between an imbalance measured by the test cell and the known imbalance of the test sample.

### Example of Imbalance Measurement Operation and Calculation

In FIG. 7E, a graph 230 of OCV as a function of time is depicted. The volume of an imbalance test cell is 0.8 mL on each side. When the cell is flushed with excess amount of electrolytes to be tested, 0.8 mL of each electrolyte (catholyte and anolyte) is retained in the cell. The cell is discharged until OCV is <0.002 V five (5) seconds after open circuit starts. Then the cell is charged with 0.2 A pulses. The pulse is turned for 0.4 seconds and turn off for 0.1 seconds. During the 0.1 second of open-circuit, the OCV is measured. Thus the current is turned on 80% of the time. This process of alternately charging and monitoring is then continued. When a time 24 seconds has elapsed, the OCV has reached 0.854 V and the charging is stopped. The curve of OCV versus time may be constructed on reviewing the data. The OCV versus time curve for this example is shown in FIG. 7E.

The slope of the curve 230 is the steepest at time=23.5 s, which corresponds to the end point of the charging. During the 23.5 seconds, the current was on 80% of the time. Thus, the total charge time was:

23.5 seconds×80%=18.8 seconds.

Since the current was 0.2 A, the cumulative total charge is:

0.2 A×18.8 s=3.76 Coulombs

The number of moles corresponding to this is obtained by dividing the cumulative total charge by the Faraday constant:

3.76 C/(96487 C/mol)=3.90 E−5 moles

Dividing by the volume of one electrolyte chamber of the test cell gives the concentration of Fe³⁺ in the neutralized electrolyte (assuming the imbalance is known to be positive imbalance):

3.90 E−5 moles/0.0008 L=0.0487 M

The imbalance of the system is the difference between Fe³⁺ in the positive electrolyte and Cr²⁺ in the negative electrolyte. This is twice the amount of Fe³⁺ in the final neutralized electrolyte. Therefore the imbalance is:

0.049 M×2=0.0974 M.

The imbalance can also be expressed as a %, assuming the electrolyte is 1.3M in both Fe and Cr, then the % imbalance is:

0.0974 M/1.3 M=7.5%

### Single Reactant Concentration Measurement Using a Reference Electrode

In some embodiments, the concentration of a single charged electrolyte reactant may be measured in a test cell. In some embodiments, such measurements may use a reference electrode measurement as described above. For example, using a reference electrode and a test cell, the concentrations of Fe³⁺ and/or Cr²⁺ may be determined individually. In some embodiments, anolyte and catholyte are not pre-mixed before filling the cell. In other words, the positive and negative electrolyte chambers of the test cell should be filled with catholyte and anolyte individually, then discharged at a known (e.g., measured or controlled) current to substantially near zero OCV. The individual concentrations of Fe³⁺ and Cr²⁺ can be determined from the curve of OCV vs. change in charged electrolyte concentrations (e.g., change in Fe³⁺−Cr²⁺) while discharging the separate electrolytes in the test cell. Thus, although current during discharge of the test cell does not need to be known when only measuring imbalance, by monitoring or controlling the current during discharge of the test cell, the concentrations of Fe³⁺ and Cr²⁺ may be measured with minimal additional effort. In any case, the discharge current need not be constant.

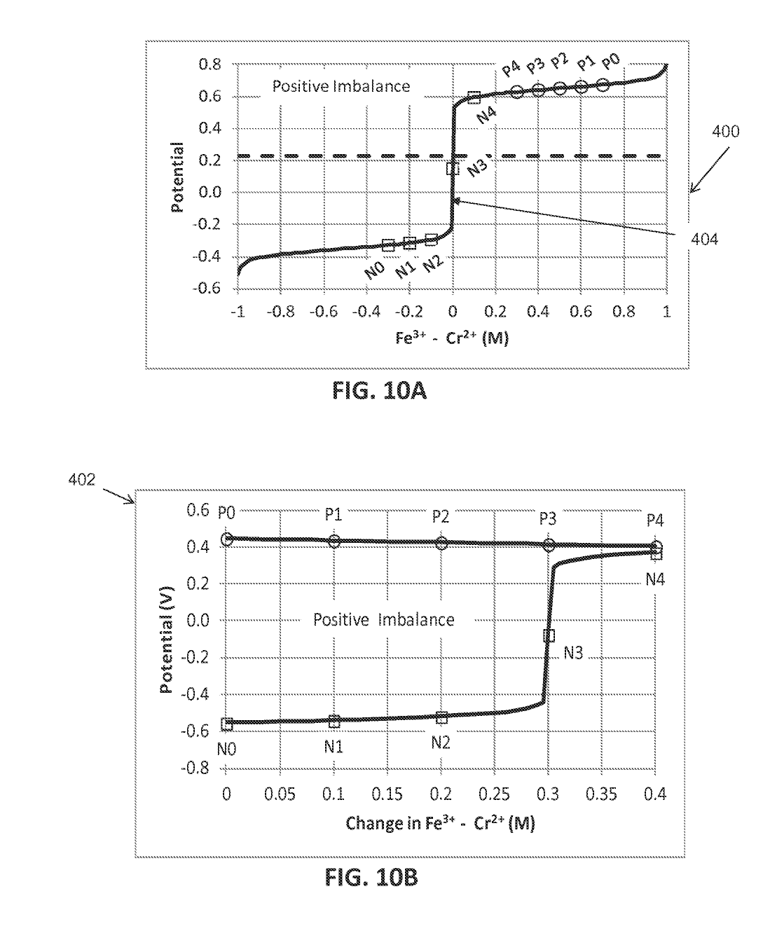

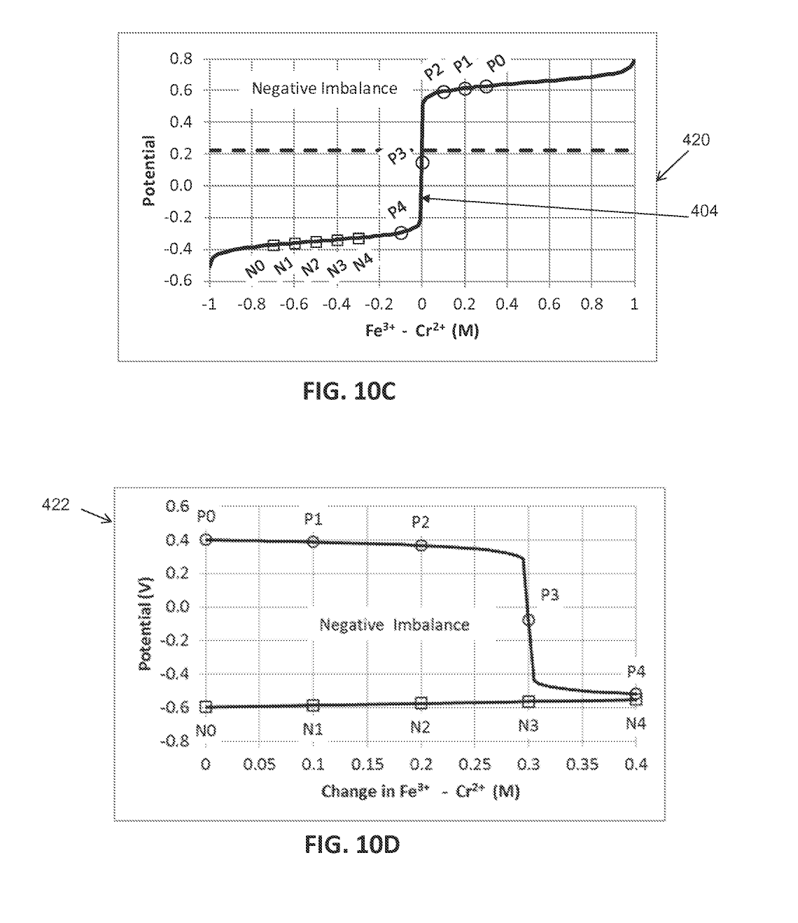

FIGS. 10A and 10B illustrate an example of graphical results 400 and 402, respectively, such a process for a system with positive imbalance. The original catholyte and anolyte in respective chambers of a test cell are represented by points P0 and N0. While discharging the test cell, the two electrolytes move toward each other along the double S curve 404. The positive electrolyte moves progressively along the curve 404 from point P0 to P1, P2, P3 and P4, and at the same time the negative electrolyte moves along the curve from point N0 to N1, N2, N3 and N4 in that order. The horizontal dashed line represents the potential measured by a Ag/AgCl reference electrode.

Using a reference electrode and the test cell OCV, the potentials of the positive and the negative electrolytes in the positive and negative test cell halves may be measured throughout the discharge process. From FIGS. 10A and 10B, it can be seen that the potential of the positive half-cell changes little from P0 to P4. By contrast, the potential of the negative half-cell changes little from N0 to N2, but rises sharply at N3. FIG. 10B illustrates a chart of potential (i.e., half-cell potentials relative to the reference potential) vs. change in charged reactant concentration (e.g., Fe³⁺−Cr²⁺). As will be clear in view of the above discussion, the x-axis of FIG. 10B is directly related to discharge time when discharging of the test cell proceeds at a known current.

In contrast to the above embodiments of imbalance measurements by coulometric titration, the methods of the present embodiments may measure the concentrations of both charged electrolyte species (e.g., Fe³⁺ and Cr²⁺) in a single test cell discharge/charge process in addition to measuring the imbalance. As described above, if only imbalance is to be measured, the test cell may be discharged to substantially 0V to obtain a starting point. In such cases, coulombs need not be counted during the discharge phase. The electrolytes may be physically mixed to obtain the same result as discharging, which would also preclude counting coulombs. By contrast, single reactant concentration measurements may involve measuring two out of three related quantities (i.e., the concentration of each charged species and the imbalance).

For instance, in a positively imbalanced pair of electrolytes, Cr²⁺ concentration and the imbalance may be measured, from which the concentration of Fe³⁺ may be calculated. In some embodiments in which coulombs are counted during discharge, the discharge stage may have two end points. For example, a first discharge end point may be the point at which a sudden jump in the measured potential of the negative half-cell versus the reference potential occurs. The second discharge end point may be the point at which the cell OCV is substantially zero (similar to the embodiments of imbalance-only measurements described above). Coulombs may be measured between a starting point and the first end point to calculate Cr²⁺ concentration. However, coulombs need not be measured for the second discharge phase between the first end point and the second end point. From that point, the test cell may be charged, and coulombs may be measured during charging to calculate imbalance as described above with reference to embodiments of imbalance measurement methods.

In FIG. 10B, the potential of the negative half of the cell (filled with anolyte) rises sharply at X=0.3. Up to this point, the potential of the positive half of the cell (filled with catholyte) has changed little. This suggests that there is more Fe³⁺ than Cr²⁺ in the system, and that the Cr²⁺ concentration in the original anolyte is 0.3M. The discharge continues until OCV reaches nearly zero. At this point the electrolytes are essentially neutralized. The imbalance in the electrolytes (e.g., Fe³⁺−Cr²⁺) may be determined by any of the imbalance measurement embodiments described above using the neutralized electrolyte in the same test cell. Once the concentration of the anolyte reactant (e.g., Cr²⁺) is known and the imbalance is known, the Fe³⁺ concentration can be calculated from Fe³⁺=imbalance+Cr²⁺.

FIGS. 10C-10D illustrate an example with graphical results 420, 422, respectively, of a similar process for a system with negative imbalance. In FIG. 10C, the original catholyte and anolyte are represented by points P0 and N0, respectively. As the test cell is discharged, the two electrolytes move toward each other along the curve 404. The positive electrolyte moves progressively from point P0 to P1, P2, P3 and P4, and at the same time the negative electrolyte moves progressively from point N0 to N1, N2, N3 and N4. The horizontal dashed line represents the potential measured by the reference electrode.

Using a reference electrode and the test cell OCV, the potentials of the positive and the negative half of the test cell can be measured throughout the discharge process. From FIGS. 10C and 10D, it can be seen that the potential of the negative half-cell changes little from N0 to N4, while the potential of the positive half-cell changes little from P0 to P2, but drops sharply at point P3. FIG. 10D illustrates a chart of the potential (i.e., half-cell potentials relative to the reference potential) vs. change in charged reactant concentration (e.g., Fe³⁺−Cr²⁺) As will be clear in view of the above discussion, the x-axis of FIG. 10D is directly related to discharge time when discharging of the test cell proceeds at a known controlled current.

In FIG. 10D, the potential of positive half of the cell (filled with catholyte) drops sharply at X=0.3. Up to this point, the potential of the negative half of the cell (filled with anolyte) has changed little. This suggests that there is more Cr²⁺ than Fe³⁺ in the system, and that the Fe³⁺ concentration in the original catholyte is 0.3M. The discharge continues until OCV reaches nearly zero. At this point the electrolytes are essentially neutralized. The imbalance in the electrolytes (e.g., Fe³⁺−Cr²⁺) may be determined by any of the imbalance measurement embodiments described above using the now-neutralized electrolyte in the same test cell. Once the concentration of the catholyte reactant (e.g., Fe³⁺) is known and the imbalance is known, the Cr²⁺ concentration may be calculated from Cr²⁺=Fe³⁺−imbalance.

Single Reactant Concentration Measurement without a Reference Electrode

In some embodiments, the concentration of a single electrolyte reactant may be measured without the use of a reference electrode by placing only that electrolyte into both electrolyte chambers of a test cell. For example, the concentration of Fe³⁺ in the catholyte may be measured by placing only the catholyte (without anolyte) in a test cell. Alternately, the concentration of Cr²⁺ in the anolyte may be measured by placing only the anolyte (without catholyte) in the test cell.

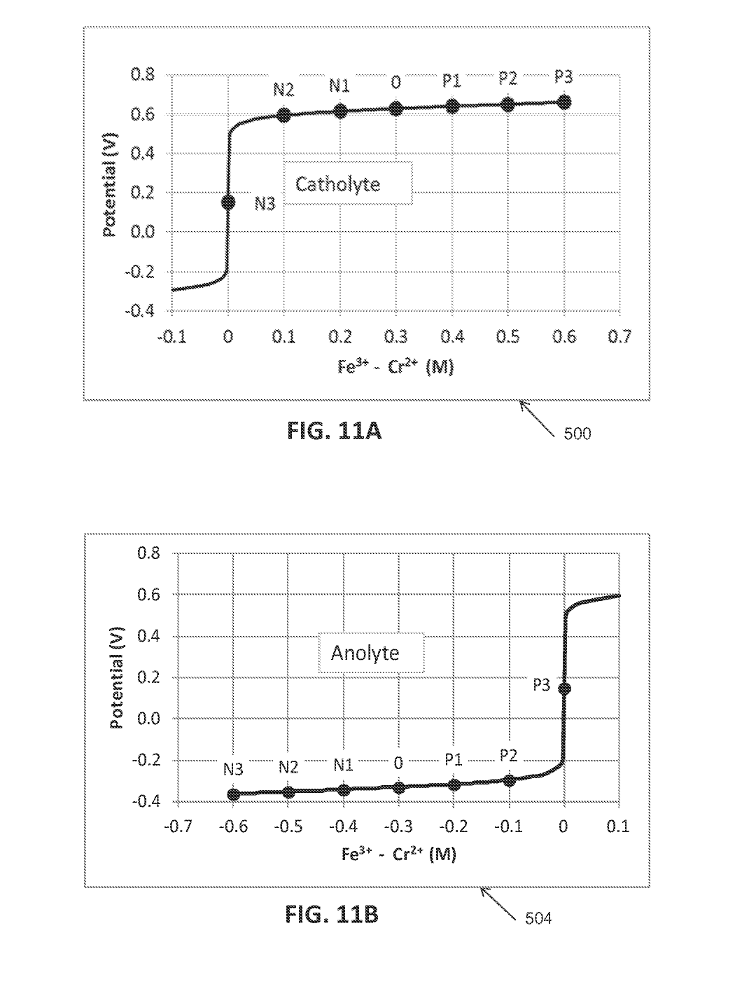

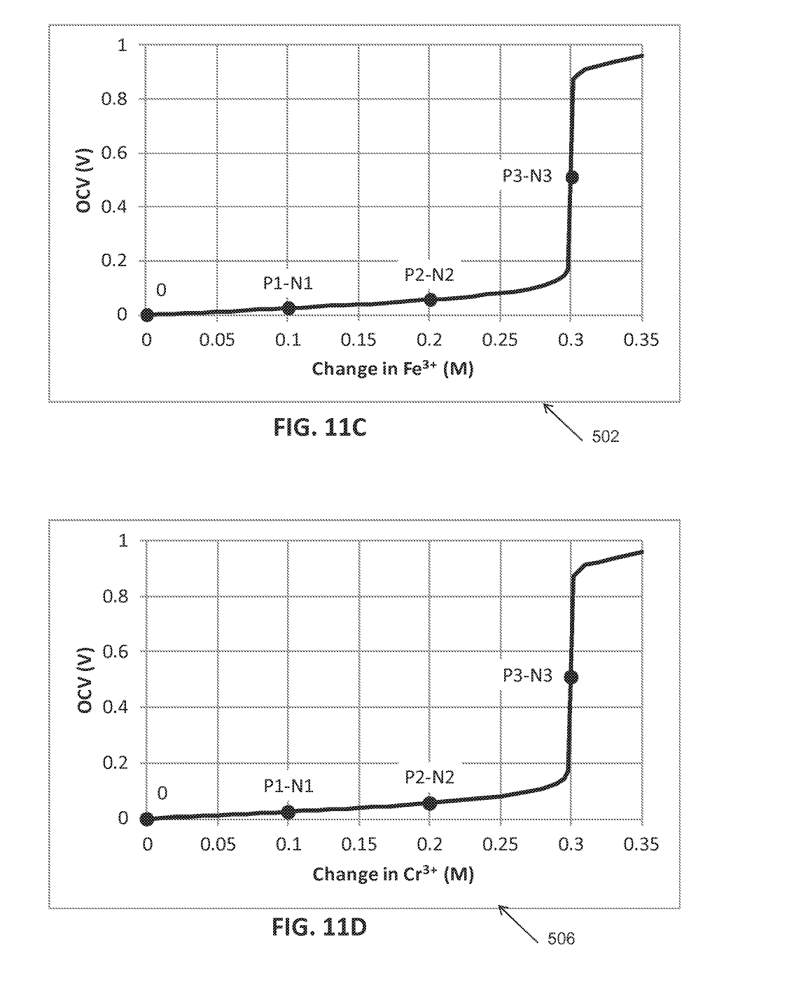

FIG. 11A illustrates a graph 500 mainly the catholyte half of the double S curve for an Fe/Cr redox couple. A catholyte with Fe³⁺ concentration=0.3M is represented by point 0. Both electrolyte chambers of a test cell may be filled with this catholyte. Since the same electrolyte is in both sides, the OCV is initially zero. The cell may then be charged with a controlled current while the OCV is measured vs. time. The time value can be converted to an equivalent concentration of Fe³⁺ using the equations described above. During charging, electrolyte on the positive side of the test cell progressively passes through points P1, P2 and P3 while the electrolyte in the negative side progresses through points N1, N2, N3.

The measured OCV represents the difference between the potentials of the positive and the negative halves of the cell. FIG. 11C illustrates a graph 502 of the OCV vs. the concentration change (i.e., the change in Fe³⁺ from the start of the test at point 0). A sharp rise in the OCV is observed at a concentration difference of Fe³⁺=0.3. This indicates that the concentration of Fe³⁺ in the original catholyte is 0.3M.

FIG. 11B and FIG. 11D illustrate graphs 504, 506, respectively, a similar embodiment for measuring the concentration of Cr²⁺ in the anolyte. FIG. 11B illustrates mainly the anolyte half of the double S curve. An anolyte with Cr²⁺ concentration=0.3M is represented by point 0. Both electrolyte chambers of a test cell may be filled with this anolyte. Since the same electrolyte is in both cell compartments, the OCV is zero. The cell may then be charged with a controlled current while the OCV is measured vs. time. The time value can be converted to an equivalent concentration of Cr²⁺ using the equations above. During charging, the electrolyte in the positive side of the test cell progressively passes through points P1, P2 and P3 in that order while the electrolyte in the negative side progresses through points N1, N2, N3.

The measured OCV is the difference between the potentials of the positive and the negative half of the cell. FIG. 11D illustrates 506 a graph of OCV vs. the change in Cr²⁺ (i.e. the change in concentration difference from the start of the test at point 0). A sharp rise in the OCV is observed at change in Cr²⁺=0.3. This indicates that the concentration of Cr²⁺ in the original anolyte is 0.3M.

The above examples illustrate measurement of the concentration of a reactant (e.g., Fe³⁺) in catholyte using only catholyte, and measurement of the concentration of a reactant (e.g., Cr²⁺) in the anolyte using only anolyte in the test cell. In either case, no reference is needed. The imbalance of the two electrolytes can then be obtained as the difference between the redox reactant (i.e., Fe³⁺−Cr²⁺).

However, in the measurement of individual concentrations without the use of a reference electrode, there are two limitations. The identity of the electrolyte being tested must be known independent of the test. A catholyte with Fe³⁺=0.3M cannot be distinguished from an anolyte with Cr²⁺=0.3M. As a result, the curve in FIG. 11B is very similar to that in FIG. 11D.

The SOO of the catholyte or the anolyte should be less than about 0.4 to use this method (e.g., without a reference electrode). If the SOO of the tested electrolyte is substantially greater than about 0.4, the measured OCV curve can give a false result that “folds over” at around an SOO=0.5 (i.e., 50% of the charge-able reactant is in a “charged” ionic state and 50% is in an “dis-charged” ionic state). For example if the total Fe concentration is 1.0, then a catholyte with Fe³⁺=0.7 is indistinguishable from that with Fe³⁺=0.3; 0.8 is indistinguishable from 0.2 etc. By controlling the timing of a test to ensure that the SOO is expected to be below the fold-over point (i.e., an SOO of 50%). The same applies to the anolyte.

### Flowing-Stagnant Method

In some cases, the above described fold-over ambiguity may be overcome with a modified method and apparatus configured to perform a test while retaining a volume of a single electrolyte (e.g., either a positive electrolyte or a negative electrolyte) in a first chamber of a monitoring cell while continuously flowing the same electrolyte through the second chamber of the monitoring cell. Such systems and methods may allow for unambiguous SOO determination when testing electrolytes over substantially the entire range of SOO.

As used in this example, the first chamber, in which an aliquot (i.e. sample portion) of electrolyte remains still during the test, may be referred to as the stagnant chamber. The second chamber through which electrolyte flows may be referred to as the flowing chamber.

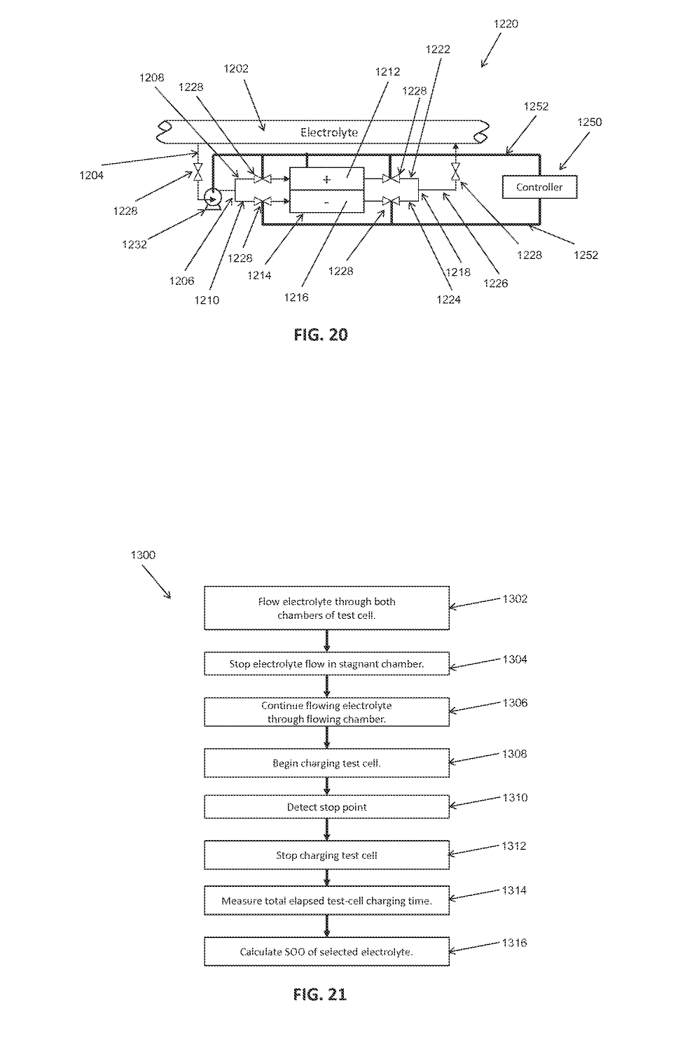

FIG. 20 illustrates an example of a monitoring cell 1214 and fluid delivery configuration 1220 suitable for use with a flowing-stagnant SOO test. The example configuration of FIG. 20 may include a source 1202 of either a positive electrolyte or a negative electrolyte. The electrolyte source may be a conduit drawing directly from an electrolyte tank (e.g., tanks 104 in FIG. 1), a conduit drawing electrolyte from a flow battery stack (e.g., stack assembly 106 in FIG. 1), or any other conduit within a flow battery system. A withdrawal conduit 1204 may be provided to withdraw electrolyte from the source 1202, and direct the electrolyte to an inlet branch 1206 with a positive leg 1208 configured to direct the electrolyte into the positive half-cell chamber 1212 of the test cell 1214 and a negative leg 1210 configured to direct the electrolyte into the negative half-cell chamber 1216 of the test cell 1214.

An outlet branch conduit 1218 with a positive leg 1222 and a negative leg 1224 and a common return conduit 1226 may be provided to return the electrolyte to the source 1202. The inlet and outlet branches 1206, 1218 may also include valves 1228 configured to stop electrolyte flow through one or both chambers 1212, 1216 of the test cell 1214. In some embodiments, only a single valve may be needed to perform a flowing-stagnant test as will be described below. For example, a single valve may be positioned in the conduit leading into the half-cell in which flow is to be stopped during the test. Alternatively, a single three-way valve may be used so selectively stop flow through one or both half-cells. In other embodiments, additional valves or other valve arrangements may also be provided as needed. In some embodiments, an electrolyte monitoring system may include a dedicated pump 1232 to move electrolytes through the test cell 1214. Alternatively, in some embodiments, the pump 1232 may be omitted.

In some cases, a test cell 1214 may be joined to only one electrolyte. In other cases, a test cell may be joined to two or more sources of electrolyte, and suitable valve arrangements may be provided and operated to direct only a selected electrolyte into the test cell 1214 for a given test.

FIG. 20 also schematically illustrates an electronic controller 1250 for monitoring and controlling elements of a monitoring system such as a test cell 1214, a pump 1232, valves 1228, etc. In this example, the electronic controller 1250 may be implemented with a bus architecture, represented generally by the bus 1252. The bus 1252 may include any number of interconnecting buses and bridges depending on the specific application and the overall constraints. The bus 1252 may be configured to link together various circuits including electrical or electromechanical components and one or more processors.

FIG. 21 is a process flow diagram illustrating an example of a flowing-stagnant SOO test process 1300. In some embodiments, the embodiments process 1300 may be conducted through the operation of a processor configured to perform the operations. While described in connection with a processor, the operations may also be performed such as through controllers, or other automated systems or individual controllers or actuators at various valves, pumps or etc., or combinations of these elements. In block 1302, a processor may be configured such that an electrolyte (e.g., a selected one of a catholyte and an anolyte) may be flowed through both chambers of the test cell, such as by operating a valve or valves, a pump, etc., or a combination of actions. In block 1304, the processor may be configured such that the electrolyte flow through the “stagnant” chamber may be stopped, such as by operating a valve or valves, a pump, etc., or a combination of actions. In block 1306, the processor may be configured such that, the electrolyte may be stopped in the stagnant chamber, while continuing to flow the electrolyte through the “flowing” chamber. In block 1308, charging of the test cell may begin (e.g., by applying a charging current and voltage to terminals of the test cell). The charging operation of block 1308 may be performed while continuing to flow electrolyte through the flowing chamber. In block 1310, the processor may be configured such that a stop point may be detected, such as a point at which a charge-state such as a SOO, SOC, charge imbalance, reactant concentration, etc., of one or more reactants may be reasonably accurately determined or assumed. In block 1312, when the processor determines that a stop point is detected, the charging may be stopped. In block 1314, the processor may be configured such that a total charging time may be calculated. In block 1316, the processor may be configured such that the SOO of the selected electrolyte may be calculated, such as based on the calculated charge time. In optional embodiments, valves may be opened upon completion of the operations of embodiment method 1300 such as to allow electrolyte to flow through the stagnant chamber before shutting off the flow of electrolyte through the test cell. Alternatively, electrolyte may flow through the test cell in between tests.

Further examples of flowing-stagnant processes will now be described with reference to FIG. 20 and FIG. 21. Typically, in a flowing-stagnant process the negative chamber 1216 of the test cell 1214 may be the flowing chamber and the positive chamber 1212 may be the stagnant chamber when testing to determine the SOO of the negative electrolyte. On the other hand, when testing to determine the SOO of the positive electrolyte, the positive chamber 1212 of the test cell 1214 may be the flowing chamber and the negative chamber 1216 may be the stagnant chamber. Establishing the flowing half-cell and the stagnant half-cell in this way, the reactant-of-interest becomes the process-limiting reactant.

For example, in the case of an Fe/Cr system, when testing a positive electrolyte with a flowing-stagnant process, a positive electrolyte may be flowed through the test cell's positive half-cell chamber and may be stagnant in the test cell's negative half-cell chamber. The test cell may be charged until all of the Fe³⁺ in the negative half-cell chamber (stagnant chamber) is reduced to Fe²⁺. Because the SOO of the flowing half-cell changes very little (as further explained below), the process is minimally sensitive to the availability of oxidizable Fe²⁺ in the flowing positive electrolyte. The number of coulombs consumed between the charging start point and the charging stop point is proportional to the quantity of Fe³⁺ available in the electrolyte prior to the start of charging.

In an example where the flowing and stagnant chambers are reversed, such as an example in which the positive electrolyte is stagnant in the positive half-cell while flowing through the negative half-cell, then the discharged form of the positive reactant (i.e., Fe²⁺ in this example) would be the process limiting reactant given that the charging process would proceed until substantially all of the available Fe²⁺ were oxidized to Fe³⁺. In such a case, the quantity of Fe³⁺ at the start of test-cell charging could be determined by simple subtraction.

One benefit of the flowing-stagnant method is that it allows for the SOO of an electrolyte to be measured when the electrolyte is at both very high SOO and at very low SOO. The flowing stagnant method may allow for the determination of SOO over very nearly the full range of SOO. The wide range of SOO determination is possible because even though a charging current is applied to the entire test cell, most of the applied charge will be built up in the aliquot of electrolyte within the stagnant chamber. The applied charge builds up in the stagnant chamber because the electrolyte in the flowing chamber may be continuously replaced by fresh electrolyte at substantially the same SOO as electrolyte that was initially directed into the stagnant chamber.

The above described flowing-stagnant methods may be further understood by way of an example. If the flowing half-cell chamber volume is 0.8 mL, and if the flow rate is 0.05 mL/s, then the mean residence time of electrolyte in the flowing half-cell chamber is 0.8 mL/(0.05 mL/s)=16 seconds. In other words, at any given moment, the flowing chamber may contain aliquots of electrolyte that have been in the flowing chamber for up to 16 seconds. On average, the electrolyte will have been in the cell for 8 seconds. If the charging current is 0.2 A, then during those 8 seconds, the cumulative total charge is 0.2 A*8 s=1.6 coulombs. The corresponding number of moles is: 1.6 C/(96487 C/mol)=1.66 E−5 moles. The corresponding change in concentration in the 0.8 mL flowing chamber is 1.66 E−5 mol/0.0008 L=0.021 M. Therefore, the concentration-based SOO of the electrolyte in the flowing chamber will tend to change by only about 0.021 M during the test-cell charging process.

Because the potential of the flowing chamber half-cell can be expected to remain approximately constant while charging the test cell, the above described flowing-stagnant methods may be used for evaluating electrolyte over very nearly the entire range of SOO. Also, when the change in SOO of the flowing chamber electrolyte can be assumed to be negligibly small, the exact flow rate of the electrolyte flowing through the flowing chamber need not be tightly controlled or measured. In some cases, the flow rate of the flowing electrolyte need not be measured or controlled at all. In other cases, it may be desirable to measure or control the flow rate of the flowing electrolyte through the flowing test-cell chamber.

In some embodiments, a cell used for a flowing-stagnant process may be a test cell such as those described above with reference to FIG. 2-FIG. 5. However, because the SOO of the flowing half-cell changes only negligibly during test-cell charging, the size of the flowing half-cell is not particularly critical. Therefore, the flowing half-cell may be much larger (or smaller) than the stagnant half-cell. In some cases, it may be desirable for the test cell to have a flowing half-cell with a substantially larger volume than a stagnant half-cell in order to reduce pumping pressure required to flow electrolyte through the flowing half-cell. The stagnant half-cell may have a small internal volume for the same reasons described above, such as decreasing the time needed to charge substantially all of the available reactant within the stagnant chamber. Test-cell charging time is related to cell volume because charging the electrolyte in a stagnant test-cell chamber relies on diffusion of the reactants to the separator interface. Minimizing the chamber volume reduces the diffusion distances required, and also reduces the mole quantity of reactants that must diffuse. At the same time, the chamber should be large enough that a representative quantity of reactants may be assumed to be present in a given aliquot of electrolyte within the chamber.

Thus, as in the examples above, a stagnant chamber may have an internal volume of about 1 mL or less, or about 0.8 mL in one particular embodiment. On the other hand, the flowing chamber may be the same size or larger (or even smaller if desired). Thus, the flowing chamber may have an internal volume of more than 1 mL.

In some cases, the flow rate of electrolyte through the flowing chamber may be maintained substantially constant throughout the test-cell charging process. The relatively small change in SOO and potential of the flowing chamber may then be calculated using the flowing-chamber volume, the electrolyte flow rate, and the charging current.

In general, the stop point at which charging should be stopped and marking an end-point of a time measurement may generally be a point at which a charge-state (e.g., SOO, SOC, charge imbalance, reactant concentration, etc.) of one or more reactants may be reasonably accurately determined or assumed. For example, as described above with reference to FIG. 7A-FIG. 7G and FIG. 10A-FIG. 11B, an identifiable stop point occurs when reactants in one of the test-cell half-cells passes through a vertical section of the potential vs. imbalance double-S shaped curve (e.g., the curves 200 of FIG. 7A, FIG. 7B, FIG. 7C, and FIG. 7G). Because the charge state (e.g., SOO, imbalance, SOC, reactant concentration, etc.) of at least one of the half-cells can be assumed at the identifiable stop-point, the charge state at the unknown starting point can be inferred based on known relationships between a measured charging time (or discharging time), and other known or know-able variables such as charging current, half-cell volume, etc.

During charging (or discharging) of the test cell, these or other recognizable stop-points may be detected in a variety of different ways. The choice of which stop-point identification method or criteria to use may depend on details of a particular instrument configuration, a degree of accuracy required, or other factors.

In some embodiments, a charging process time end-point may be based on a point in time at which the slope of the measured voltage vs. time curve reaches a maximum. For example, in some embodiments, measurement data may be sampled and stored in a digital memory during a single test. Such measurement data may be analyzed by a processor to identify a maximum voltage vs. time slope. In some embodiments, the maximum slope may only be identifiable after it has passed. In such embodiments, the end-point time may be identified and applied retroactively.

In some embodiments, measurement data may include a time-series of OCV values with associated time stamps. In other embodiments, measurement data may comprise only a series of voltage values, and time information associated with each sample value may be implicit based on the position of the sample and a known sampling rate. In some embodiments, measurement data may also include an indication of a time or sample-value at which a charging process is initiated.

In other embodiments, detecting a stop point may comprise detecting a voltage threshold of the test cell. For example, a pre-determined end-point test cell voltage (OCV or CCV) may be determined based on the known theoretical relationship between voltage and electrolyte concentration as shown and described above. In some embodiments, an ideal end-point voltage may change over time due to changing resistance of the test cell. Such changes may be identified by calibration and appropriate adjustments to end-point voltage or other adjustments may be made. Different end-point voltage values may be implied by voltage/concentration curves for different redox couples.

In some embodiments, both a threshold voltage and a peak slope may be used to identify a measurement time end-point. For example, in some embodiments a processor may begin analyzing data to identify a maximum voltage vs. time slope only after a threshold voltage has been reached. In other embodiments, the calculation of a maximum slope may utilize other related quantities, such as voltage versus coulombs or others.

As in some examples above, the start point of an elapsed time measurement may be a time at which charging begins. In other cases, the start point of an elapsed time measurement may be a time at which a measured test-cell voltage reaches a predetermined point. If charging current is applied continuously, a total charging time measurement may be a contiguous time period from a start time to a stop point time. If the charging current is pulsed by alternating charging time intervals with open-circuit time intervals, then the time measurement may be the sum of all charging time intervals applied between the start point time and the stop point time. Similarly, if an elapsed time measurement is to be made during discharging, a total discharge time may be obtained as a contiguous time interval for a continuous current, or as a sum of discharging time intervals for a pulsed discharge current.

Once a total charge time measurement has been obtained and/or determined (e.g., by summing intervals), the unknown charge-state of the target electrolyte may be determined. For the sake of simplicity of explanation, a constant charging current will be assumed in this example. If current is represented by variable “I”, the total charge time is represented by variable “t,” and Faraday's constant is represented by “F,” then the number of moles (“n”) of reactant converted from a “discharged” form to a “charged” form during the test-cell charging process is:

n=(t*I)/F [12]

Because the test cell charging process proceeds from a starting point at which a desired reactant concentration is unknown to a known stop point at which some aspect of the electrolyte's charge state (e.g., SOO, SOC, imbalance or charged reactant concentration) is known, then the desired information may be obtained directly or by simple subtraction from a known stop point.

In alternative embodiments, a flowing-stagnant process may also be used in combination with other methods described herein, including methods involving both positive and negative electrolytes in a test-cell, such as the example methods described above utilizing neutralized electrolytes. Flowing-stagnant methods involving both positive and negative electrolytes in a test-cell may be beneficial in detecting very high degrees of imbalance. For example, equal volumes of positive and negative electrolytes may be neutralized by mixing or by discharging (as described above), and placed into a stagnant chamber of a test cell. The positive electrolyte or the negative electrolyte of the flow battery may be flowed through the flowing chamber of the test cell while the test cell is charged. Once a suitable stop point is reached, the total charging time may be determined, and the electrolyte charge imbalance may be determined as described elsewhere herein. This method allows for measurement of the mixed (neutralized) electrolyte from an SOO of −100% to +100%, which corresponds to an imbalance of −200% (at which point both electrolytes have a highly negative potential) to +200% (at which point both electrolytes have a highly positive potential). In general, such situations are very extreme and unusual cases.

### Examples of Control Processes

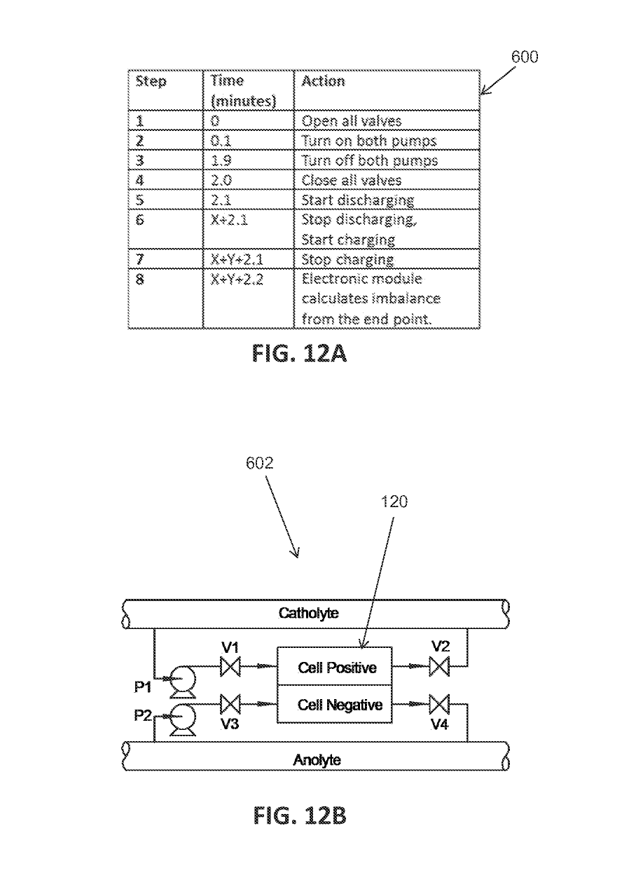

FIGS. 12A-14B provide examples of control process embodiments that may be controlled by an electronic module as described above with reference to FIG. 1. The numeric time values provided in FIGS. 12A, 13A and 14A are provided primarily for reference and simplicity of explanation. Actual times may vary substantially from these values and may depend on many factors such as the time response of various system components.

FIG. 12A is a process flow diagram 600 illustrating an embodiment of a control process that may be executed by an electronic module to control an imbalance measurement process using an electrolyte monitoring system with a through-flow fluid delivery system 602 as illustrated for example in FIG. 12B. The process s of FIG. 12A comprises the steps numbered 1-8, which may occur at the approximate times in the second column.

At the start of the measurement process of FIG. 12A, all valves V1, V2, V3 and V4 are all opened in step 1 at time t=0. Step two may begin once all valves are open, which may be at about time t=0.1 minutes. During step two, both pumps P1 and P2 may be started to pump electrolyte through the cell 120. Step two may proceed for a sufficient time and at a sufficient pump flow rate to flush out all electrolyte previously in the test cell 120 and in all tubing of the fluid delivery system 350. Once the test cell 120 is full of fresh electrolytes, the pumps may be shut off at step 3 which may be at a time of about t=1.9 minutes, and the valves may be closed (step 4) at t=2 minutes.

The test cell may then be discharged in a discharge process (step 5) that may begin at about time t=2.1 minutes. The discharge process (step 5) may continue until a desired near-zero OCV is reached, e.g. about 0.002V in some embodiments. The time interval needed to discharge the test cell to the desired near-zero point will be variable and is therefore represented in FIG. 12A by the variable ‘X’. The variable discharge time ‘X’ may depend on the value of the desired near-zero OCV, the value of an applied current, the degree of electrolyte imbalance, the SOO of the respective electrolytes, and other factors. As discussed above, some of these variable factors may be known, and in some embodiments the variable discharge time (‘X’) may be measured and evaluated to determine a reactant concentration. In some embodiments, the timer interval X may be a few seconds up to about 3 minutes. In some embodiments, the discharge process may be stopped and a charging process may be started (step 6) at a time of about t=X+2.1. As discussed above, the time interval for the charging process (step 6) will also be variable, and may proceed until a desired measurement end-point is reached. The variable test cell charge time is represented as ‘Y’ in FIG. 12A. Thus, the charging process may be stopped at time t=X+Y+2.1 minutes. In some embodiments, Y may be a few seconds up to about 4 minutes or more.

Once the time interval Y is determined at the completion of step 7, the electronic module may calculate the imbalance from the value of the time interval Y and other known system variables and constants as described above. In some embodiments, the electronic module may then communicate a measured imbalance value back to the main flow battery control system.

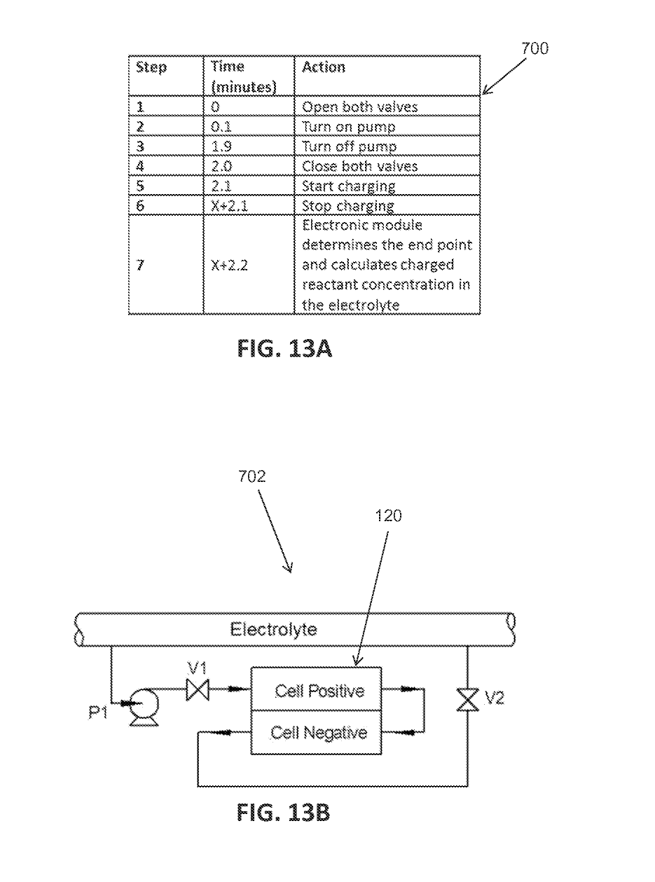

FIG. 13A is a process flow diagram 700 illustrating an embodiment of a control process that may be executed by an electronic module to control an electrolyte reactant concentration measurement process using an electrolyte monitoring system with a through-flow fluid delivery system 702 configured to direct only one electrolyte through the test cell 120 as illustrated for example in FIG. 13B. The process of FIG. 13A will now be described with reference to the catholyte of an Fe/Cr flow battery electrolyte. In some embodiments, the same process may be performed to make a corresponding measurement of the concentration of a charged reactant concentration in an anolyte. In some embodiments, the catholyte concentration measurement process and the anolyte concentration measurement process may be performed simultaneously in separate test cells, which may be located adjacent respective electrolyte storage tanks in some embodiments.

The process of FIG. 13A may begin at time t=0 by opening both valves V1 and V2. At time t=0.1 minutes, the pump P1 may be turned on (step 2), and catholyte may be pumped through the test cell 120 for a sufficient time and at a sufficient flow rate to flush out all electrolyte previously in the test cell and all tubing of the fluid delivery system 352. In some embodiments, the pumps may be stopped (step 3) at about time t=1.9 minutes, and both valves V1 and V2 may be closed (step 4) at about time t=2.0 minutes. Once filled with a single electrolyte, the test cell 120 may have an OCV of zero. The test cell 120 may be charged (step 5) beginning at time t=2.1 minutes. The test cell 120 may be charged until a desired end-point is reached as described above. As the test cell 120 is charged, the test cell OCV will increase from zero, and the rate of OCV change will eventually reach a maximum before slowing down again. In some embodiments, the end-point may be the point at which the rate of OCV change versus time reaches a maximum before slowing down again. The charging time interval variable is represented by ‘X’ in FIG. 13A. Charging may be stopped (step 6) once the end-point is reached at time t=X+2.1. The electronic module may then calculate the charged electrolyte concentration (e.g., Fe³⁺), and may communicate the measured concentration value to the main flow battery control system.

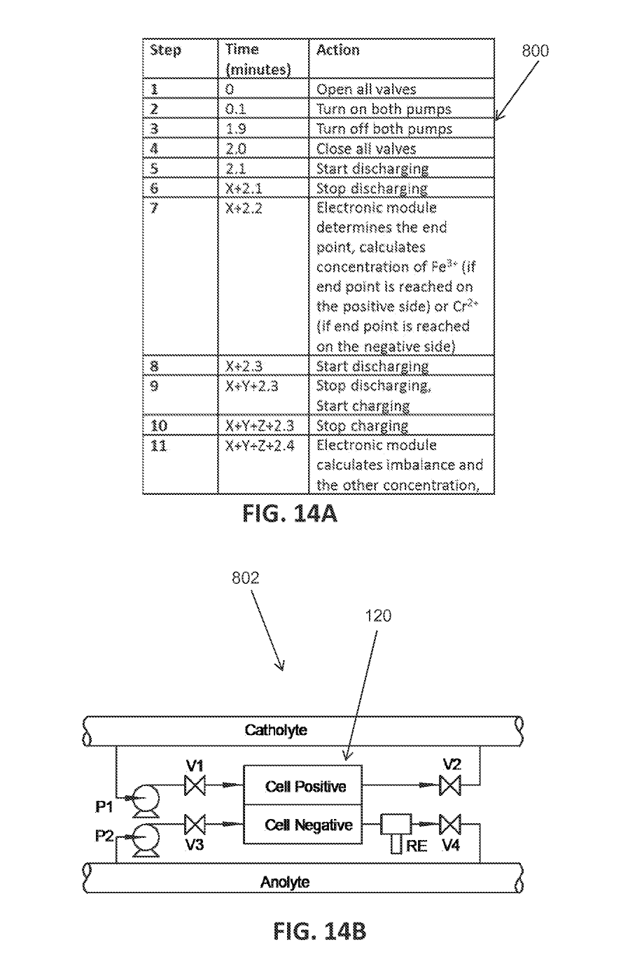

FIG. 14A is a process flow diagram 800 illustrating an embodiment of a control process that may be executed by an electronic module to control an electrolyte reactant concentration measurement process and an imbalance measurement using an electrolyte monitoring system with a through-flow fluid delivery system 802, a reference electrode ‘RE’, and a test cell 120 as illustrated for example in FIG. 14B.

At the start of the measurement process of FIG. 14A, all valves V1, V2, V3 and V4 are all opened in step 1 at time t=0. Step two may begin once all valves are open, which may be at about time t=0.1 minutes. During step two, both pumps P1 and P2 may be started to pump electrolyte through the cell 120. Step two may proceed for a sufficient time and at a sufficient pump flow rate to flush out all electrolyte previously in the test cell 120 and in all tubing of the fluid delivery system 350. Once the test cell 120 is full of fresh electrolytes, the pumps may be shut off at step 3 which may be at a time of about t=1.9 minutes, and the valves may be closed (step 4) at about t=2 minutes.

The test cell 120 may then be discharged in a discharge process (step 5) that may begin at about time t=2.1 minutes. The discharge process (step 5) may continue until a pre-determined end-point. The time interval needed to discharge the test cell to the desired end-point will be variable and is therefore represented in FIG. 14A by the variable ‘X’. The end-point at which the discharging process is stopped (step 6) may be based on the rate of change of half-cell potential relative to the reference electrode. For example, if the electrolytes are known to have a negative imbalance (as determined by a reference electrode measurement as described above), the discharging end point may be the point at which the rate of change of the positive half-cell versus the reference electrode potential reaches a maximum before slowing down again. Alternatively, if the electrolytes are known to have a positive imbalance (as determined by a reference electrode measurement as described above), the discharging end-point may be the point at which the rate of change of the negative half-cell versus the reference electrode potential reaches a maximum before slowing down again. In other words, the measurement end-point may be the point at which dV/dt is a maximum (where V is potential, and t is time).

The electronic module may then determine the value of the elapsed discharge time (X), and may calculate the concentration of the indicated electrolyte. For example, the indicated electrolyte species may be Fe³⁺ if the end point is reached on the positive side, or may be Cr²⁺ if the end point is reached on the negative side. In some embodiments, the electronic module may then communicate the measured concentration value to the main flow battery control system in step 7 at about time t=X+2.2.

The test cell 120 may then be fully discharged to a near-zero point (step 8 at about time t=X+2.3 minutes) as described above with reference to the process of FIG. 12A. The discharge process may be stopped when the test cell OCV reaches a desired near-zero point (e.g., about 0.002V in some embodiments), which may take a few seconds up to about 2 minutes, depending on several factors. The time interval for the second discharge stage may also be variable and is represented as ‘Y’ in FIG. 14A. Once the near-zero point is reached, charging of the test cell 120 may begin (step 9). The test cell 120 may be charged until a desired imbalance measurement end-point is reached as discussed above. The charging time interval is represented in FIG. 14A as ‘Z’. Thus, the charging process may be stopped (step 10) at time X+Y+Z+2.3 minutes. The electronic module may then calculate the degree of electrolyte imbalance (step 11) and communicate the result to the main flow battery control system.

In various embodiments, once a desired analyte value has been determined (e.g., an SOO of a positive or negative electrolyte, an imbalance, an SOC, or a reactant concentration), the obtained information may be used to control operation of one or more flow battery components. For example, an imbalance value, or one or more SOO values may be communicated to a rebalancing system so that the rebalancing system may adjust a concentration of one or more reactants in order to establish a desired electrolyte balance in the SOOs of the positive and negative electrolytes. Such control may be achieved by operating various components such as one or more pumps, one or more valves, a rebalancing cell voltage, a rebalancing cell current, other aspects of a rebalancing system, or other components. Alternatively, a communications device may be used to communicate an alarm, a control signal, or other information derived from or describing the obtained analyte value to another system or to a human operator. Such communication device may be configured to transmit an email, transmit an SMS message, illuminate a light, sound an alarm, or any other communication.

### Chrono-Potentiometry Methods

In alternative embodiments, the degree of cell imbalance may be monitored using chrono-potentiometry without reference electrodes. In some embodiments of this method, the electrolytes may be pumped into a test cell (e.g. a cell such as those described above with reference to FIGS. 1-2). In some embodiments, a volume of positive electrolyte may be pumped into a positive side of the test cell and an approximately equal volume of negative electrolyte may be pumped into a negative side of the test cell.

Once the test cell is full of electrolyte, the electrolyte flow may be shut off. The cell may be held at open circuit while the open-circuit voltage (OCV) is recorded over a period of time. As the active species ions diffuse across the separator, the OCV will decrease over time. The imbalance may then be determined from the shape of the OCV-time curve. The total time for a measurable degree of change in OCV is significantly affected by the volume of electrolytes in the test cell. Thus, in some embodiments, the test cell may be made small enough that the OCV-time curve may cover a significant voltage range (e.g., 0.9 to 0.6V) within a short time (e.g. on the order of minutes).

At any moment, including during open circuit, the Fe³⁺ in the catholyte diffuses through the separator to the anolyte and reacts with Cr²⁺. The Cr²⁺ in the anolyte diffuses to the catholyte and reacts with Fe³⁺. In either case, the reaction is:

Fe³⁺+Cr²⁺→Fe²⁺+Cr³⁺ [14]

The rate of decrease in either Fe³⁺ or Cr²⁺ concentration is proportional to the sum of the two concentrations. This is described by a set of differential equations:

dFe³⁺/dt=−k(Fe³⁺+Cr²⁺) [15]

dCr²⁺/dt=−k(Fe³⁺+Cr²⁺) [16]

where ‘k’ is a rate constant and ‘t’ is time. The magnitude of K may be obtained experimentally, and is mainly dependent on properties of the separator and the operating temperature. For example, K is larger for a more permeable separator.

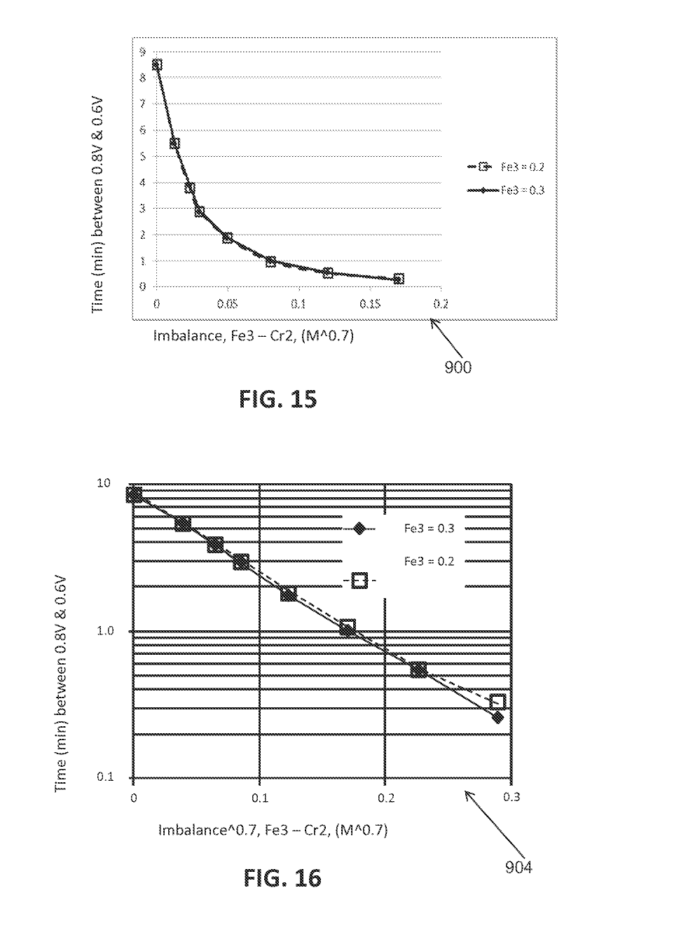

When the value of K, and the initial concentrations of Fe³⁺ and Cr²⁺ are known, equations [7] and [8] may be solved numerically to give the concentrations of Fe³⁺ and Cr²⁺ as functions of time. The OCV of the cell may then be calculated from the Nernst equation. Practically, these values are not easily known, but the OCV of the cell at different time may be obtained from measurement. The above model may then be fitted to data of measured OCV vs. time. The initial concentrations of Fe³⁺ and Cr²⁺ and the value of K may be determined from the fitting. A graphical example 900 of such fitting is shown in FIG. 15.

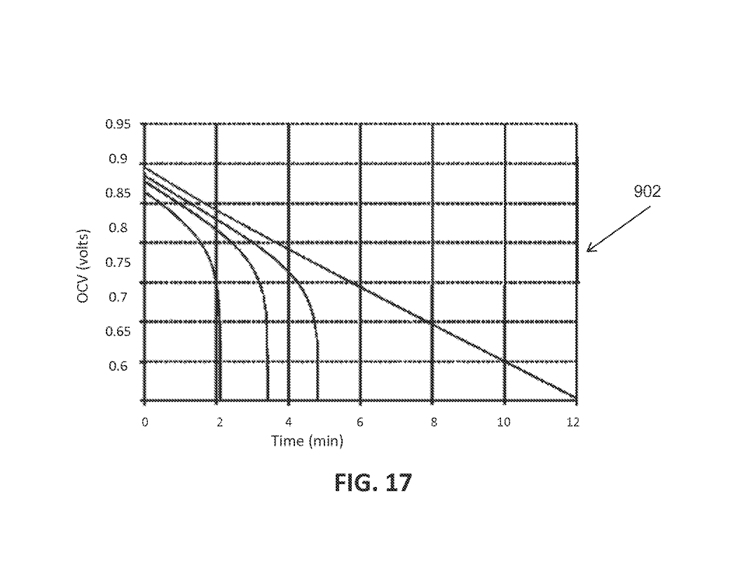

FIG. 17 illustrates a graph 902 of an embodiment of an experimentally-determined relationship between cell OCV and time for various concentrations of electrolyte active materials for a particular cell arrangement. It has been found that the experimental data closely agrees with the mathematical model.

Thus, in some embodiments, this model may be used as a response for determining the extent of imbalance. For example, in some embodiments, the electrolyte concentration may be determined by measuring the time between two known voltages along the curve and matching the results to the model. For example, measuring the time between the test cell voltage reaching 0.8V and 0.6V may provide a consistently usable response because it is independent of the starting SOC. Such a relationship is shown in FIG. 15. In one embodiment, a plot of log(time) vs. imbalance raised to the 0.7th power is quite useful because it is linear, as shown in graph 904 in FIG. 16.

The examples, equations and methods for quantifying and monitoring electrolyte imbalances above are described with reference to an Fe/Cr flow battery chemistry. However the same principles and concepts may be applied to any flow battery chemistry without departing from the spirit of the invention.

Embodiments of redox flow battery cells, stack assemblies and systems described herein may be used with any electrochemical reactant combinations that include reactants dissolved in an electrolyte. One example is a stack assembly containing the vanadium reactants V(II)/V(III) or V²⁺/V³⁺ at the negative electrode (anolyte) and V(IV)/V(V) or V⁴⁺/V⁵⁺ at the positive electrode (catholyte). The anolyte and catholyte reactants in such a system are dissolved in sulfuric acid. This type of battery is often called the all-vanadium battery because both the anolyte and catholyte contain vanadium species. Other combinations of reactants in a flow battery that may utilize the features and advantages of the systems described herein include Sn (anolyte)/Fe (catholyte), Mn (anolyte)/Fe (catholyte), V (anolyte)/Fe (catholyte), V (anolyte)/Ce (catholyte), V (anolyte)/Br₂ (catholyte), Fe (anolyte)/Br₂ (catholyte), and S (anolyte)/Br₂ (catholyte). In each of these example chemistries, the reactants are present as dissolved ionic species in the electrolytes, which permits the advantageous use of configured cascade flow battery cell and stack assembly designs in which cells have different physical, chemical or electrochemical properties along the cascade flow path (e.g. cell size, type of membrane or separator, type and amount of catalyst, etc.). A further example of a workable redox flow battery chemistry and system is provided in U.S. Pat. No. 6,475,661, the entire contents of which are incorporated herein by reference. Many of the embodiments herein may be applied to so-called “hybrid” flow batteries (such as a zinc/bromine battery system) which use only a single flowing electrolyte.

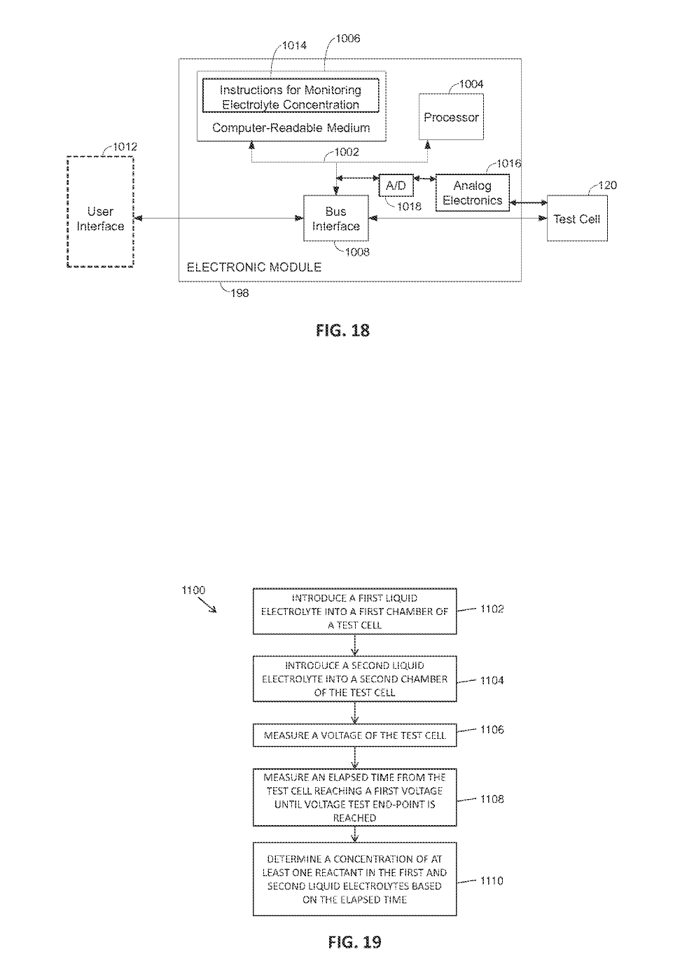

FIG. 18 is a schematic block diagram illustrating an example of a hardware implementation for an electronic controller 198 for monitoring and controlling a test cell 120. In this example, the electronic controller 198 may be implemented with a bus architecture, represented generally by the bus 1002. The bus 1002 may include any number of interconnecting buses and bridges depending on the specific application of the electronic controller 198 and the overall design constraints. The bus 1002 links together various circuits including one or more processors, represented generally by the processor 1004, and computer-readable media, represented generally by the computer-readable medium 1006. The bus 1002 may also link various other circuits such as timing sources, peripherals, sensors, and power management circuits, which are well known in the art, and therefore, will not be described any further. A bus interface 1008 provides an interface between the bus 1002 and the test cell 120. Depending upon the nature of the apparatus, a user interface 1012 (e.g., keypad, display, speaker, microphone, joystick) may also be provided. The processor 1004 is responsible for managing the bus 1002 and general processing, including the execution of software or instructions 1014 stored on the computer-readable medium 1006. The software, when executed by the processor 1004, causes the electronic controller 116 to perform the various functions described above for any particular apparatus. The computer-readable medium 1006 may also be used for storing data that is manipulated by the processor 1004 when executing software or instructions 1014. In some embodiments, analog electronics 1016 may also be joined to the bus 1002 by an analog-to-digital converter (and in some embodiments a digital-to-analog converter) 1018. Analog electronics 1016 may be provided to perform various analog functions such as voltage regulation, electric current measurement, current regulation or other functions.

FIG. 19 illustrates a method 1100 of determining a degree of electrolyte imbalance in a reduction-oxidation (redox) flow battery system. In method 1100, a monitoring system may introduce a first liquid electrolyte into a first chamber of a test cell at process block 1102 and introduce a second liquid electrolyte into a second chamber of the test cell in block 1104 (concurrently or at different times). The monitoring system may measure a voltage of the test cell in block 1106. The monitoring system may measure an elapsed time from the test cell reaching a first voltage until voltage test end-point is reached in block 1108. In block 1110, a monitoring system a may determine a concentration of at least one reactant in the first and second liquid electrolytes based on the elapsed time.

The foregoing description of the various embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein, and instead the claims should be accorded the widest scope consistent with the principles and novel features disclosed herein.

In particular, materials and manufacturing techniques may be employed as within the level of those with skill in the relevant art. Furthermore, reference to a singular item, includes the possibility that there are plural of the same items present. More specifically, as used herein and in the appended claims, the singular forms “a,” “and,” “said,” and “the” include plural referents unless the context clearly dictates otherwise. As used herein, unless explicitly stated otherwise, the term “or” is inclusive of all presented alternatives, and means essentially the same as the commonly used phrase “and/or.” Thus, for example the phrase “A or B may be blue” may mean any of the following: A alone is blue, B alone is blue, both A and B are blue, and A, B and C are blue. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation. Unless defined otherwise herein, all technical and scientific terms used herein have the same meaning as commonly understood by one of ordinary skill in the art to which this invention belongs.

What is claimed is:

1. A method of evaluating a state-of-oxidation (SOO) of an electrolyte in a reduction-oxidation (redox) flow battery system, the method comprising:
flowing a first sample of a first liquid electrolyte having an unknown first SOO into a first chamber of a first test cell in a first flow;
flowing a second sample of the first liquid electrolyte having the first SOO into a second chamber of the first test cell in a second flow;
stopping the first flow; and
while the first flow is stopped, continuing the second flow at a known flow rate while performing:
charging the first test cell with a first known charging current from a first charging start time to a first predetermined stop point;
measuring a first open circuit voltage of the first test cell while charging the first test cell;
measuring a first total charging time from the first charging start time until the first predetermined stop point is reached; and
determining the first SOO of the first liquid electrolyte based on the first total charging time.

2. The method of claim 1, further comprising:
flowing a first sample of a second liquid electrolyte having an unknown second SOO into a first chamber of a second test cell in a third flow;
introducing a second sample of the second liquid electrolyte having the second SOO into a second chamber of the second test cell in a fourth flow;
stopping the third flow; and
while the third flow is stopped, continuing the fourth flow at a known flow rate while performing:
charging the second test cell with a second known charging current from a second charging start time to a second predetermined stop point;
measuring a second open circuit voltage of the second test cell while charging the second test cell;
measuring a second total charging time from the second charging start time until the second predetermined stop point is reached; and
determining the second SOO of the second liquid electrolyte based on the second total charging time.

3. The method of claim 2, wherein a first internal volume of the first half-cell chamber is substantially equal to a second internal volume of the second half-cell chamber.

4. The method of claim 2, further comprising determining an imbalance between the first state of oxidation and the second state of oxidation by calculating a difference between the first state of oxidation and the second state of oxidation.

5. The method of claim 1, wherein charging the first test cell with the first known charging current comprises charging the first test cell using pulsed charging in which in the first known charging current is applied during a first time interval followed by a second time interval during which the first known charging current is switched off, the application of the first known charging current during the first time interval followed by the switching off of the first known charging current during the second time interval is repeated until the first predetermined stop point is reached.

6. The method of claim 5, wherein measuring he first open circuit voltage of the first test cell comprises measuring the first open circuit voltage of the first test cell during the second time intervals when the first known charging current is switched off.

7. The method of claim 1, wherein the first predetermined stop point comprises a point in time at which a maximum rate of change of the first measured open circuit voltage is reached.

8. The method of claim 1, wherein the first predetermined stop point comprises a predetermined open-circuit voltage for the first open circuit voltage.

9. The method of claim 1, wherein the first predetermined stop point comprises a predetermined closed-circuit voltage.

10. The method of claim 1, wherein the first liquid electrolyte is a positive electrolyte of the flow battery, and wherein charging the first cell increases the state of oxidation of the positive electrolyte to a second state of oxidation.

11. The method of claim 10, wherein the first state of oxidation describes a quantity of Fe³⁺ in the first liquid electrolyte.

12. The method of claim 2, wherein the second state of oxidation describes a quantity of Cr²⁺ in the first liquid electrolyte.

13. The method of claim 1, further comprising measuring an electric potential of at least one of the first liquid electrolyte and the second liquid electrolyte with a reference electrode.

14. A redox flow battery comprising an electrolyte monitoring system for controlling operation of the flow battery according to a state of oxidation (SOO) of at least one flow battery electrolyte, the electrolyte monitoring system comprising:
a first test cell having a first half-cell chamber and a second half-cell chamber, and a separator membrane separating the first half-cell chamber from the second half-cell chamber;
a first supply conduit directing a first flow of a first electrolyte having an unknown first SOO into the first half-cell chamber of the first test cell and a first return conduit returning the first flow of the first electrolyte to a source of the first electrolyte;
a second supply conduit directing a second flow of the first electrolyte into the second half-cell chamber of the first test cell and a second return conduit returning the second flow of the first electrolyte to the source of the first electrolyte;
at least one electronically-controlled valve configured to stop the first flow of the first electrolyte through the first half-cell of the first test cell; and
a first electronic controller configured to control the at least one electronically-controlled valve and the first test cell, the first electronic controller comprising instructions for performing operations comprising:
stopping the first flow; and
continuing the second flow at a known flow rate while performing operations comprising:
charging the first test cell with a first known charging current from a first charging start time to a first predetermined stop point;
measuring a first open circuit voltage of the first test cell while charging the first test cell;
measuring a first total charging time from the first charging start time until the first predetermined stop point is reached; and
determining the first SOO of the first electrolyte based on the first total charging time.

15. The redox flow battery of claim 14, wherein the first electrolyte is a positive flow battery electrolyte, and wherein the first half-cell is a negative half-cell of the test cell.

16. The redox flow battery of claim 14, wherein the first electrolyte is a negative flow battery electrolyte, and wherein the first half-cell is a positive half-cell of the test cell.

17. The redox flow battery of claim 14, wherein the first SOO is associated with a quantity of Fe³⁺ in the first liquid electrolyte.

18. The redox flow battery of claim 14, wherein a first internal volume of the first half-cell chamber is substantially equal to a second internal volume of the second half-cell chamber.

19. The redox flow battery of claim 14, wherein a first internal volume of the first half-cell chamber is smaller than a second internal volume of the second half-cell chamber.

20. The redox flow battery of claim 14, wherein the electrolyte monitoring system further comprises:
a second test cell having a first half-cell chamber, a second half-cell chamber, and a separator membrane separating the first half-cell chamber from the second half-cell chamber;
a third supply conduit directing a third flow of a second electrolyte having a unknown second state-of-oxidation into the first half-cell chamber of the second test cell and a third return conduit returning the third flow of the second electrolyte to a source of the second electrolyte;
a fourth supply conduit directing a fourth flow of the second electrolyte into the second half-cell chamber of the second test cell and a fourth return conduit returning the fourth flow of the second electrolyte to the source of the second electrolyte;
a second at least one electronically-controlled valve configured to stop the third flow of the second electrolyte through the first half-cell of the second test cell; and
a second electronic controller configured to control the second at least one electronically-controlled valve and the second test cell, the second electronic controller comprising instructions to perform operations comprising:
stopping the third flow; and
while the third flow is stopped, continuing the fourth flow at a known flow rate while performing operations comprising:
charging the second test cell with a second known charging current from a second charging start time to a second predetermined stop point;
measuring a second open circuit voltage of the second test cell while charging the second test cell;
measuring a second total charging time from the second charging start time until the second predetermined stop point is reached; and
determining the second state of oxidation of the second electrolyte based on the first total charging time.

21. The redox flow battery of claim 20, wherein one of: the first electronic controller; and the second electronic controller further comprises instructions for performing operations comprising determining a degree of imbalance between the first state of oxidation and the second state of oxidation by calculating a difference between the first state of oxidation and the second state of oxidation.

22. The redox flow battery of claim 20, wherein the second state of oxidation describes a quantity of Cr²⁺ in the first liquid electrolyte.
